(19) United States
(12) Patent Application Publication
(10) Pub. No.: US 2010/0104740 A1
(43) Pub. Date: Apr. 29, 2010

(54) METHOD FOR DISCHARGING LIQUID BODY, METHOD FOR MANUFACTURING COLOR FILTER, AND METHOD FOR MANUFACTURING ORGANIC EL DEVICE

(75) Inventor: Toru SHINOHARA, Suwa (JP)

Correspondence Address: GLOBAL IP COUNSELORS, LLP, 1233 20TH STREET, NW, SUITE 700, WASHINGTON, DC, 20036-2680, US

(73) Assignee: SEIKO EPSON CORPORATION, Tokyo (JP)

(21) Appl. No.: 12/578,982

(22) Filed: Oct. 14, 2009

(30) Foreign Application Priority Data
Oct. 28, 2008 (JP) 2008-276424

(51) Int. Cl. B05D 5/06; G01F 11/08

(52) U.S. Cl. 427/66; 222/1

(57) ABSTRACT

A method for discharging a liquid body includes discharging the liquid body to a plurality of discharged regions provided to a substrate from a plurality of nozzles each of which discharges the liquid body as a droplet and that are disposed in a linear manner as a nozzle line while the nozzle line and the substrate are relatively moved in a main scan direction approximately perpendicular to an arrangement direction of the nozzle line. Each of the plurality of the discharged regions is composed of a first discharged region and a second discharged region. An area of the first discharged region is different from an area of the second discharged region. In the discharging the liquid body, a discharge condition of the liquid body to the first discharged region is set to be different from a discharge condition of the liquid body to the second discharged region.

### CROSS-REFERENCE TO RELATED APPLICATIONS

This application claims priority to Japanese Application No. 2008-276424 filed on Oct. 28, 2008. The entire disclosure of Japanese Application No. 2008-276424 is incorporated herein by reference.

### BACKGROUND

1. Technical Field

The present invention relates to a method for discharging a liquid body, a method for manufacturing a color filter, and a method for manufacturing an organic EL device.

2. Related Art

Methods for discharging liquid bodies containing functional materials are applied to form films for color filters of liquid crystal displays and organic EL devices, for example. Liquid body discharge devices are used to discharge the liquid bodies. The liquid body discharge device includes a droplet discharge mechanism called a droplet discharge head. The droplet discharge head has a plurality of nozzles formed in a regular manner. In manufacturing the color filters and organic EL devices, liquid bodies containing functional materials are discharged from the nozzles as droplets to substrates or the like to form thin films made of the functional materials.

Recently, display devices have been widely used and provided with various sized panels. There have been also demands for the display devices with high image quality. In order to meet the demands, films for color filters and organic EL devices are required to be precisely formed in high density. Accordingly, it has become important that liquid bodies are precisely discharged in high density to substrates having various sizes. In addition, there are demands for manufacturing multiple panels from a single large substrate for improving panel productivity to meet an increasing demand for panels of display devices. In this case, various layouts are examined to increase the efficiency of the numbers of panels per substrate or to manufacture panels having different sizes from a single substrate. Some layout may allow panels including pixel regions having different sizes to be mixedly provided in a single large substrate. The pixel region means a minimum unit region to which a liquid body is discharged.

JP-A-2006-187758, for example, discloses such a droplet discharge device that discharges a liquid body from a droplet discharge head to a workpiece (substrate) as a droplet and a method for discharging a droplet in which, while the workpiece is moved in a first direction and a second direction perpendicular to the first direction, the liquid body is discharged, from nozzles of the droplet discharge head disposed in a plurality of carriages having been positioned in advance in the second direction, to draw a pattern.

The droplet discharge device of the above example discharges the liquid body to a predetermined region on the substrate from the nozzles having been positioned in advance. The nozzles are arranged in a linear manner with a constant pitch. The pixel region serving as the minimum unit region to which the liquid body is discharged is formed in an approximately rectangular shape. Because of the structure, the liquid body is discharged to the pixel region preferably from as many as possible of nozzles in order to prevent the liquid body from being discharged at an eccentrically located position in the region as well as to disperse the discharge variation of the nozzles.

When the pixel regions having different sizes are mixedly disposed in a single substrate, however, the number of nozzles that can discharge the liquid body to a specific region may be limited in some pixel region, which may resulting in the liquid body being discharged at an eccentrically located position in the region to cause uneven discharged amount of the liquid body in the region. The uneven discharged amount of the liquid body may cause uneven thickness of a thin film formed in the region. The occurrence of the uneven thickness of the thin film such as functional films of color filters of liquid crystal displays and organic EL devices causes to degrade the image quality of manufactured displays. There has been, thus, a problem in that it is difficult to efficiently manufacture panels having stable quality when the panels that include pixel regions having different sizes are mixedly disposed in a single large substrate.

### SUMMARY

The invention intends to solve at least part of the above problem, and can be realized by the following aspects.

According to a first aspect of the invention, a method for discharging a liquid body includes discharging the liquid body to a plurality of discharged regions provided to a substrate from a plurality of nozzles each of which discharges the liquid body as a droplet and that are disposed in a linear manner as a nozzle line while the nozzle line and the substrate are relatively moved in a main scan direction approximately perpendicular to an arrangement direction of the nozzle line. Each of the plurality of the discharged regions is composed of a first discharged region and a second discharged region. An area of the first discharged region is different from an area of the second discharged region. In the step of discharging the liquid body, a discharge condition of the liquid body to the first discharged region is set to be different from a discharge condition of the liquid body to the second discharged region.

According to the method, the discharge condition to supply the liquid body to the first discharged region and the discharge condition to supply the liquid body to the second discharged region from the nozzles can be set to be different from each other. The optimum discharge condition can be selected for each of the first and the second discharged regions so as to meet the respective required specifications or features. The liquid body, thus, can be supplied to the every discharged region with the proper discharge condition even though the discharged regions having different specifications or conditions are mixedly disposed in a single substrate. As a result, problems such as an uneven discharge amount of the liquid body can be reduced. Consequently, the method enables at least two kinds of thin films to be manufactured with stable quality, contributing to improve the productivity of the films.

The number of nozzles that can discharge the liquid body is limited for the discharged regions having a small area. According to the method, the discharge condition to supply the liquid body to the first discharged region and the discharge condition to supply the liquid body to the second discharged region can be set to be different from each other. Therefore, for the discharged region having a small area, a predetermined liquid body can also be stably supplied by changing the discharge condition. As a result, problems such as an uneven discharge amount of the liquid body can be reduced, and at least two kinds of thin films can be manufactured with stable quality. Consequently, the method can contribute to improve the productivity of the films.

In the method, a droplet applying density of the droplet discharged from the nozzles in the first discharged area may be set to be different from a droplet applying density of the droplet discharged from the nozzles in the second discharged area.

The method can adjust the droplet applying density, which is one of the discharge conditions, in the first discharged region and in the second discharged region respectively. Accordingly, for the discharged region to which a small number of nozzles that can discharge the liquid body is allocated, a predetermined liquid body can be stably supplied by increasing the droplet applying density. As a result, problems such as an uneven discharge amount of the liquid body can be reduced, and at least two kinds of thin films can be manufactured with stable quality. Consequently, the method can contribute to improve the productivity of the films.

In the method, a relative speed of the substrate and the nozzle line in the main scan direction in discharging the liquid body to the first discharged area may be set to be different from a relative speed of the substrate and the nozzle line in the main scan direction in discharging the liquid body to the second discharged area.

The method can adjust the relative movement speed of the substrate and the nozzle line in the main scan direction in the first discharged region and the second discharged region respectively. Accordingly, a droplet landed interval in the main scan direction in the discharged region can be changed. In other words, the droplet applying density in the main scan direction, which is one of the discharge conditions, can be changed in the first discharged region and in the second discharged region respectively.

In the method, a discharge period in which the liquid body is discharged from the nozzles to the first discharged area may be set to be different from a discharge period in which the liquid body is discharged from the nozzles to the second discharged area.

The method can adjust the period in which the liquid body is discharged from the nozzles in the first discharged region and the second discharged region respectively. Accordingly, a droplet landed interval in the main scan direction in the discharged region can be changed. In other words, the droplet applying density in the main scan direction, which is one of the discharge conditions, can be changed in the first discharged region and in the second discharged region respectively.

In the method, a discharge amount of the liquid body discharged from the nozzles to the first discharged region is set to be different from a discharge amount of the liquid body discharged from the nozzles to the second discharged region.

The method can adjust the amount of the liquid body discharged from the nozzles, which is one of the discharge conditions, in the first discharged region and in the second discharged region respectively. Accordingly, for the discharged region to which a small number of nozzles that can discharge the liquid body is allocated, a predetermined liquid body can be stably supplied by increasing the amount of the liquid body discharged from the nozzles. As a result, problems such as an uneven discharge amount of the liquid body can be reduced, and at least two kinds of thin films can be manufactured with stable quality. Consequently, the method can contribute to improve the productivity of the films.

In the step of discharging the liquid body may further include relatively moving the nozzle line and the substrate in a sub scan direction perpendicular to the main scan direction while the nozzle line and the substrate are relatively moved a plurality of times in the main scan direction. In addition, at least one of the number of relative movements in the main scan direction and a moving amount in the sub scan direction in discharging the liquid body to the first discharged region may be set to be different from at least one of the number of relative movements in the main scan direction and the moving amount in the sub scan direction in discharging the liquid body to the second discharged region.

The method can adjust the relative movement amount (distance) of the nozzle line and the substrate in the sub scan direction, while the discharge movement in the main scan direction is carried out, in the first discharged region and the second discharged region respectively. The discharge movement in the main scan direction can be carried out for a predetermined number of times in the first discharged region and the second discharged region respectively. In other words, the droplet landed interval in the sub scan direction can be adjusted for every discharged region. Specifically, the droplet applying density in the sub scan direction, which is one of the discharge conditions, can be changed in the first discharged region and in the second discharged region respectively.

In the method, the first and the second discharged regions may be formed in an approximately rectangular shape, and a long side direction of the first discharged region on the substrate may be disposed approximately in parallel with a long side direction of the second discharged region.

In the method, the first and the second discharged regions may be formed in an approximately rectangular shape, and a long side direction of the first discharged region on the substrate may be disposed approximately perpendicular to a long side direction of the second discharged region.

When panels having different sizes are manufactured from a single large substrate, some layout may allow discharged regions that have different sizes and are disposed at different locations to be mixedly provided in a single large substrate. When the first discharged region and the second discharged region are disposed so as to be approximately perpendicular to each other, the long side direction of one of the regions is in parallel with the nozzle line direction whereas the short side direction of the other one of the regions is in parallel with the nozzle line direction. Because of this arrangement, the limited number of nozzles that can discharge the liquid body is allocated to the discharged region disposed so that the short side direction is in parallel with the nozzle line direction.

According to the method, the discharge condition to supply the liquid body to the first discharged region and the discharge condition to supply the liquid body to the second discharged region can be set to be different from each other. Accordingly, for the discharged region disposed so that the short side direction is in parallel with the nozzle line direction, a predetermined liquid body can be stably supplied by changing the discharge condition. As a result, problems such as an uneven discharge amount of the liquid body can be reduced, and at least two kinds of thin films can be manufactured with stable quality. Consequently, the method can contribute to improve the productivity of the films.

According to a second aspect of the invention, a method for manufacturing a color filter includes discharging a plurality of colored liquid bodies containing colored layer forming materials to a plurality of discharged regions including first discharged regions and second discharged regions on a substrate by using the method for discharging a liquid body of the first aspect, and solidifying the discharged liquid bodies so as to form a plurality of colored layers.

The method can reduce the problem of the liquid body being eccentrically discharged in the first and the second discharged regions that have different specifications and conditions. As a result, at least two kinds of color filters that have colored layers disposed in different directions can be manufactured with high quality and high productivity.

According to a third aspect of the invention, a method for manufacturing an organic EL element that includes a plurality of organic EL elements having functional layers having light emitting layers, includes discharging a liquid body containing a light emitting layer forming material to a plurality of discharged regions including first discharged regions and second discharged regions on a substrate by using the method for discharging a liquid body of the first aspect, and solidifying the discharged liquid body so as to form the light emitting layers.

The method can reduce the unevenness of the thicknesses of the light emitting layers formed in the first and the second discharged regions that have different specifications and conditions. As a result, at least two kinds of organic EL devices that have organic EL elements disposed in different directions can be manufactured with high quality and high productivity.

### BRIEF DESCRIPTION OF THE DRAWINGS

The invention will be described with reference to the accompanying drawings, wherein like numbers reference like elements.

FIG. 1 is a perspective view schematically showing a structure of a liquid body discharge device.

FIGS. 2A and 2B are views schematically showing a structure of a droplet discharge head.

FIG. 3 is a schematic plan view showing an arrangement of the liquid droplet discharge heads in a head unit.

FIG. 4 is a block diagram showing a control system of the liquid body discharge device.

FIGS. 5A and 5B are graphs explaining a control of the droplet discharge head.

FIGS. 6A and 6B are schematic views showing a color filter.

FIG. 7 is a flowchart showing a method for manufacturing a color filter.

FIGS. 8A to 8D are schematic sectional views showing the method for manufacturing a color filter.

FIG. 9 is a schematic plan view showing a relative arrangement of the head unit and a mother substrate in a first example.

FIGS. 10A and 10B are schematic plan views showing an arrangement of droplets in the first example.

FIGS. 11A and 11B are schematic plan views showing an arrangement of droplets in a third example.

FIG. 12 is a schematic plan view showing a relative arrangement of the head unit and the mother substrate in a fourth example.

FIGS. 13A to 13C are schematic plan views showing an arrangement of droplets in the fourth example.

FIG. 14 is a schematic plan view showing a relative arrangement of the head unit and the mother substrate in a fifth example.

FIG. 15 is a schematic sectional view showing a structure of an essential part of an organic EL device.

FIG. 16 is a flowchart showing a method for manufacturing an organic EL device.

FIGS. 17A to 17F are schematic sectional views showing the method for manufacturing an organic EL device.

### DESCRIPTION OF EXEMPLARY EMBODIMENT

The invention is described by referring to an exemplified case of manufacturing a color filter having a plurality of colored layers in a plurality of pixel regions that are partitioned on a substrate. The colored layer, which is an element included in a pixel, is formed with droplets of a liquid body. The liquid body contains a colored layer forming material and is discharged from a plurality of nozzles to a pixel region as the droplets. A liquid body discharge device described below is used for discharging the liquid body as the droplets.

Structure of Liquid Body Discharge Device

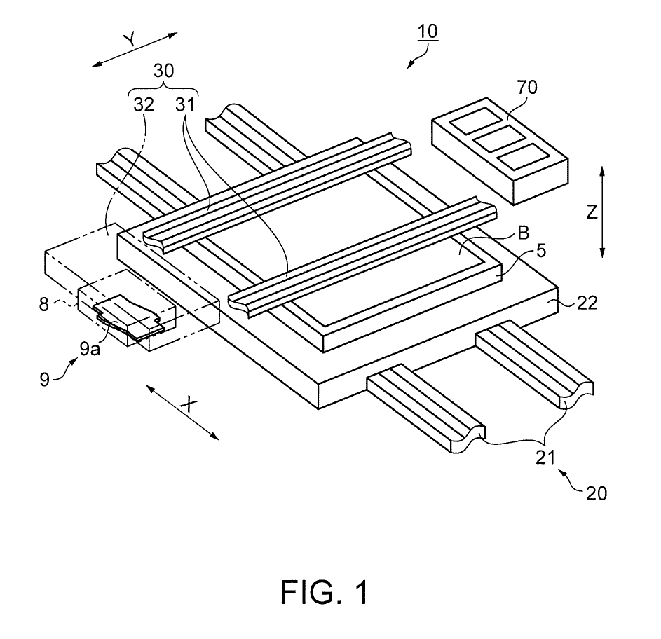

First, a liquid body discharge device including a droplet discharge head that discharges a liquid body is described with reference to FIG. 1. FIG. 1 is a perspective view schematically showing a structure of the liquid body discharge device.

As shown in FIG. 1, a liquid body discharge device 10 includes a substrate moving mechanism 20 that moves a substrate B having a discharged region (a film forming region) in a main scan direction, and a head moving mechanism 30 that moves a head unit 9 having a plurality of droplet discharge heads in a sub scan direction. The liquid body discharge device 10 discharges a liquid body as droplets from a plurality of droplet discharge heads mounted to the head unit 9 while changing a relative position between the substrate B and the head unit 9, forming a predetermined functional film on the substrate B with the liquid body. In FIG. 1, an X direction indicates a direction in which the substrate B moves i.e., the main scan direction, a Y direction indicates a direction in which the unit 9 moves, i.e., the sub scan direction, and a Z direction is perpendicular to the X direction and the Y direction.

For example, when a color filter having filter elements of three colors red, green, and blue is manufactured by using the liquid body discharge device 10, one of liquid bodies of three colors red, green, and blue is discharged from respective droplet discharge heads of the liquid body discharge device 10 as droplets to respective film forming regions on the substrate B, thereby forming filter elements of three colors red, green, and blue.

Here, each component of the liquid body discharge device 10 is described.

The substrate moving mechanism 20 includes a pair of guide rails 21, a moving table 22 that moves along the pair of guide rails 21, and a stage 5 that is provided on the moving table 22 and is capable of sucking and fixing the substrate B. The moving table 22 is moved in the X direction (the main scan direction) by an air slider and a linear motor, which are not shown but disposed inside the guide rails 21.

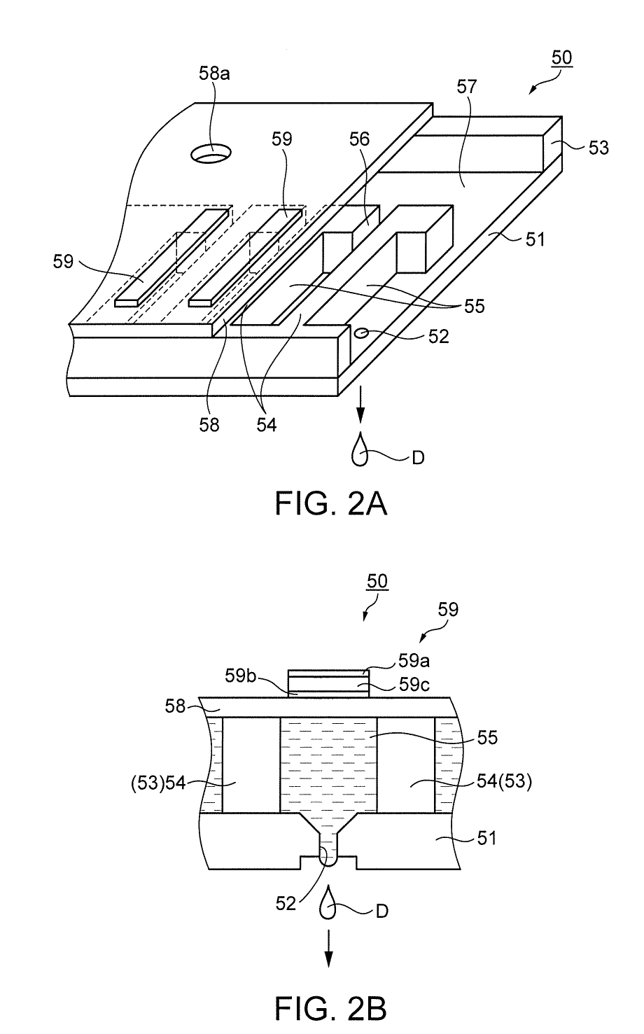

The head moving mechanism 30 includes a pair of guide rails 31 and a first moving stage 32 moving along the pair of guide rails 31. The first moving stage 32 includes a carriage 8. The carriage 8 includes the head unit 9 including a plurality of droplet discharge heads 50 (refer to FIG. 2) attached thereto. The first moving stage 32 is capable of moving the carriage 8 in the Y direction (the sub scan direction). The carriage 8 is capable of disposing the head unit 9 so as to face the substrate B in the Z direction with a predetermined distance therebetween.

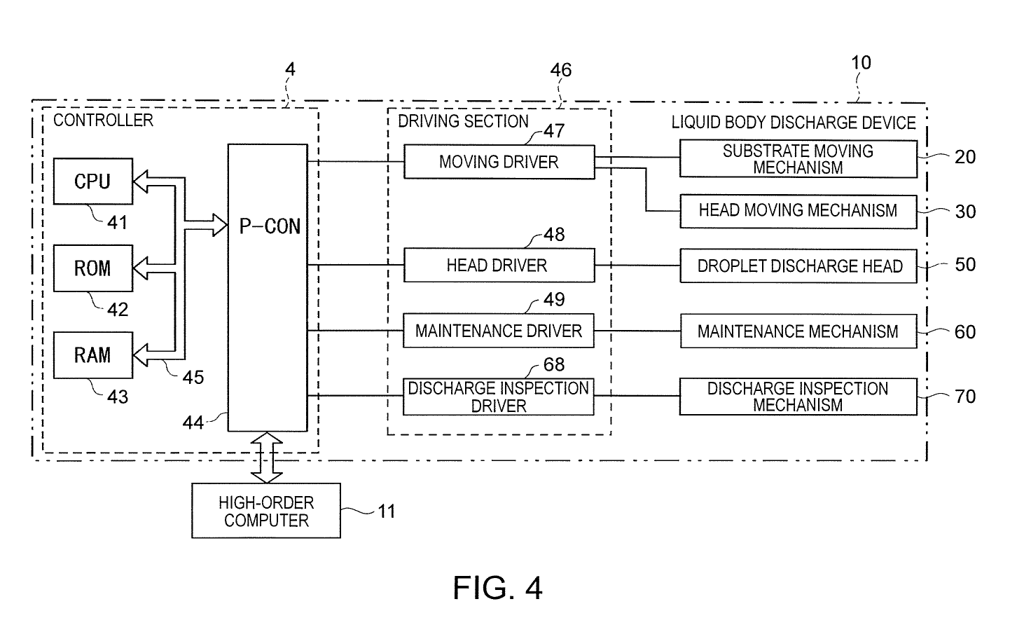

In addition to the above-described structure, the liquid body discharge device 10 includes a discharge inspection mechanism 70 having measuring equipment such as an electronic balance. The discharge inspection mechanism 70 receives the liquid body discharged from each droplet discharge head 50 or each nozzle to measure the discharged weight. The liquid body discharge device 10 further includes a maintenance mechanism 60 (refer to FIG. 4) for maintenance such as eliminating cloggings of the nozzles of the plurality of the droplet discharge heads 50 mounted to the head unit 9, and a liquid body supply mechanism for supplying the liquid body to the droplet discharge heads 50. These mechanisms are controlled by a controller 4 (refer to FIG. 4). In FIG. 1, the controller 4, the liquid body supply mechanism, and the maintenance mechanism 60 are not shown.

Droplet Discharge Head

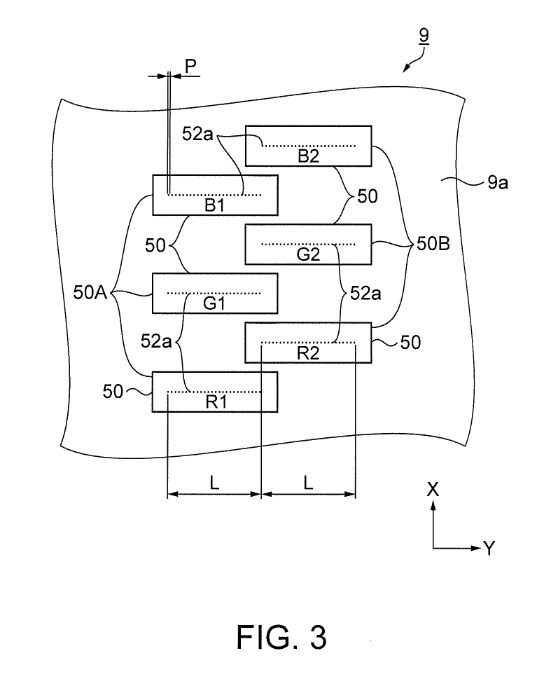

Here, the droplet discharge head including a plurality of nozzles is described with reference to FIGS. 2A and 2B, and FIG. 3. FIGS. 2A and 2B are schematic views showing a structure of the droplet discharge head. FIG. 2A is a schematic exploded perspective view and FIG. 2B is a sectional view showing a structure of a nozzle section. FIG. 3 is a schematic plan view showing an arrangement of the droplet discharge heads in the head unit. Specifically, it is viewed from a side facing the substrate B. The X direction and the Y direction shown in FIG. 3 respectively indicate the same direction as the X direction and the Y direction in FIG. 1 indicate.

As shown in FIGS. 2A and 2B, the droplet discharge head 50 is structured by sequentially laminating and bonding a nozzle plate 51 having a plurality of nozzles 52 that discharge liquid droplets D, a cavity plate 53 having partition walls 54 for partitioning cavities 55 each of which communicates with one of the nozzles 52, and an vibration plate 58 having vibrators 59 each corresponding to one of the cavities 55 as a driving element.

The cavity plate 53 has the partition walls 54 partitioning the cavities 55 communicating with the nozzles 52 and flow paths 56 and 57 for filling the cavities 55 with the liquid body. The flow path 57 is sandwiched by the nozzle plate 51 and the vibration plate 58, and a resulting space serves as a reservoir for reserving the liquid body. The liquid body is supplied from the liquid body supply mechanism through a piping and a supply hole 58a formed in the vibration plate 58 to be reserved in the reservoir. Thereafter the liquid body flows through the flow path 56 to fill each of the cavities 55.

As shown in FIG. 2B, the vibrator 59 is a piezoelectric element that is composed of a piezo element 59c and a pair of electrodes 59a and 59b sandwiching the piezo element 59c. A driving waveform is externally applied to the pair of electrodes 59a and 59b as a driving signal to deform the vibration plate 58 bonded with the vibrator 59. This deformation increases a volume of the cavity 55 partitioned by the partition walls 54, thereby drawing the liquid body into the cavity 55 from the reservoir. Then, upon completion of applying the driving waveform, the vibration plate 58 returns to its original shape and pressurizes the liquid body that fills the cavity 55. As a result, the liquid body can be discharged as the droplets D from the nozzle 52. Controlling the driving waveform applied to the piezo element 59c allows controlling the discharge of the liquid body of each nozzle 52.

As shown in FIG. 3, the droplet discharge heads 50 are disposed on a head plate 9a of the head unit 9. On the head plate 9a, a total of six droplet discharge heads 50 are provided, i.e., a head group 50A composed of three droplet discharge heads 50 and a head group 50B also composed of three droplet discharge heads 50. In this case, the droplet discharge head 50 (a head R1) of the head group 50A discharges the same kind of liquid body as the droplet discharge head 50 (a head R2) of the head group 50B discharges. The other heads G1, G2 and B1, B2, also discharge the respective liquid bodies in the same manner as the heads R1 and R2. That is, the head unit 9 is adapted to enable three different kinds of liquid bodies to be discharged.

Each droplet discharge head 50 includes a nozzle line 52a that is composed of a plurality (180 pieces) of the nozzles 52 arranged at a predetermined nozzle pitch P. Accordingly, each droplet discharge head 50 has a discharge width of a length of L. The heads R1 and R2 are arranged in the main scan direction in a parallel manner so that the nozzle lines 52a adjacent when viewed from the main scan direction (the X direction) are continued with the nozzle pitch P therebetween in the sub scan direction (the Y direction) orthogonal to the main scan direction. Accordingly, the heads R1 and R2 have the discharge width of a length of 2 L.

While the head 50 has one row of the nozzle line 52a in the embodiment, the number of nozzle lines is not limited to this. The droplet discharge head 50 may have a plurality of the nozzle lines 52a that are arranged with a certain interval in the X direction and shifted by a half of the pitch P (P/2) in the Y direction. As a result, the pitch P substantively becomes narrower, and the droplets D can be discharged with high fineness.

Control System of Liquid Body Discharge Device

Next, a control system of the liquid body discharge device 10 is described with reference to FIG. 4. FIG. 4 is a block diagram showing the control system of the liquid body discharge device 10.

As shown in FIG. 4, the control system of the liquid body discharge device 10 includes: a driving section 46 having various kinds of drivers to drive the droplet discharge heads 50, the substrate moving mechanism 20, the head moving mechanism 30, and the like; and a controller 4 that controls the liquid body discharge device 10 including the driving section 46. The driving section 46 includes: a moving driver 47 drive-controlling each linear motor of the substrate moving mechanism 20 and the head moving mechanism 30; a head driver 48 discharge-controlling the liquid droplet discharging heads 50; a maintenance driver 49 drive-controlling each maintenance unit of the maintenance mechanism 60; and a discharge inspection driver 68 controlling the discharge inspection mechanism 70.

The controller 4 includes a CPU 41, a ROM 42, a RAM 43, and a P-CON 44, which are coupled each other through a bus 45. A high-order computer 11 is coupled to the P-CON 44. The ROM 42 has a control program region for storing a control program and the like to be processed by the CPU 41 and a control data region for storing control data and the like to be used to perform a drawing operation, a function recovery processing, and the like.

The RAM 43 has various kinds of storage sections such as a pattern data storage section storing pattern data to be used to draw patterns on the substrate B, and is used as various kinds of work regions for a control processing. The P-CON 44 is coupled to the various drivers and the like for the driving section 46. Additionally, the P-CON 44 has a logic circuit to cover the functions of the CPU 41 as well as to handle interface signals between the CPU 41 and peripheral circuits. Therefore, the P-CON 44 takes various kinds of instructions from the high-order computer 11 in the bus 45 directly or after processing them, and outputs data and control signals that are outputted from the CPU 41 and the like to the bus 45 to the driving section 46 directly or after processing them in conjunction with the CPU 41.

The CPU 41 controls the liquid body discharge device 10 as a whole in the following manner. The CPU 41 inputs various kinds of detection signals, various kinds of commands, various kinds of data, and the like through the P-CON 44 in accordance with the control program in the ROM 42, and processes the various kinds of data and the like in the RAM 43. Thereafter, the CPU 41 outputs various kinds of control signals to the driving section 46 and the like through the P-CON 44. For example, the CPU 41 controls the droplet discharge heads 50, the substrate moving mechanism 20, and the head moving mechanism 30 so that the head unit 9 and the workpiece W are disposed opposite each other. Then, the head unit 9 and the substrate B relatively move. In synchronization with the relative movement, the liquid body is discharged as the droplets D from a predetermined number of nozzles 52 in each droplet discharge head 50 mounted to the head unit 9 so as to form a pattern on the substrate B.

Here, discharging the liquid body in synchronization with the movement of the substrate B in the X direction is referred to as a main scan, whereas moving the head unit 9 in the Y direction is referred to as a sub scan. The liquid body discharge device 10 of the embodiment can discharge the liquid body by repeating the combination of the main scan and the sub scan a plurality of times. In this regard, the moving speed and the number of reciprocating movements of the substrate B with respect to the droplet discharge head 50 in the main scan direction, for example, can be controlled by controlling the substrate moving mechanism 20. Likewise, the moving amount (distance) of the droplet discharge head 50 with respect to the substrate B in the sub scan direction can be controlled by controlling the head moving mechanism 30.

The high-order computer 11 can not only send control information such as control programs and control data to the liquid body discharge device 10 but also modify the control information. The high-order computer 11 also has a function as an arrangement information generation section that generates arrangement information to arrange droplets D of a liquid body of a necessary amount for every discharged region on the substrate B based on positional information of the nozzles 52. The arrangement information, which is represented, for example, as a bitmap, includes: a classification of the nozzle 52 to discharge droplets and the nozzle 52 to be in a waiting state and a discharge position of the droplet D in a discharged region (in other words, a relative position of the substrate B and the nozzle 52); the arrangement number of droplets D (in other words, the number of discharges and a discharge ratio in every nozzle 52); and an on/off, discharge timing, and the like of the plurality of the nozzles 52 in the main scan.

Drive-Control of Droplet Discharge Head

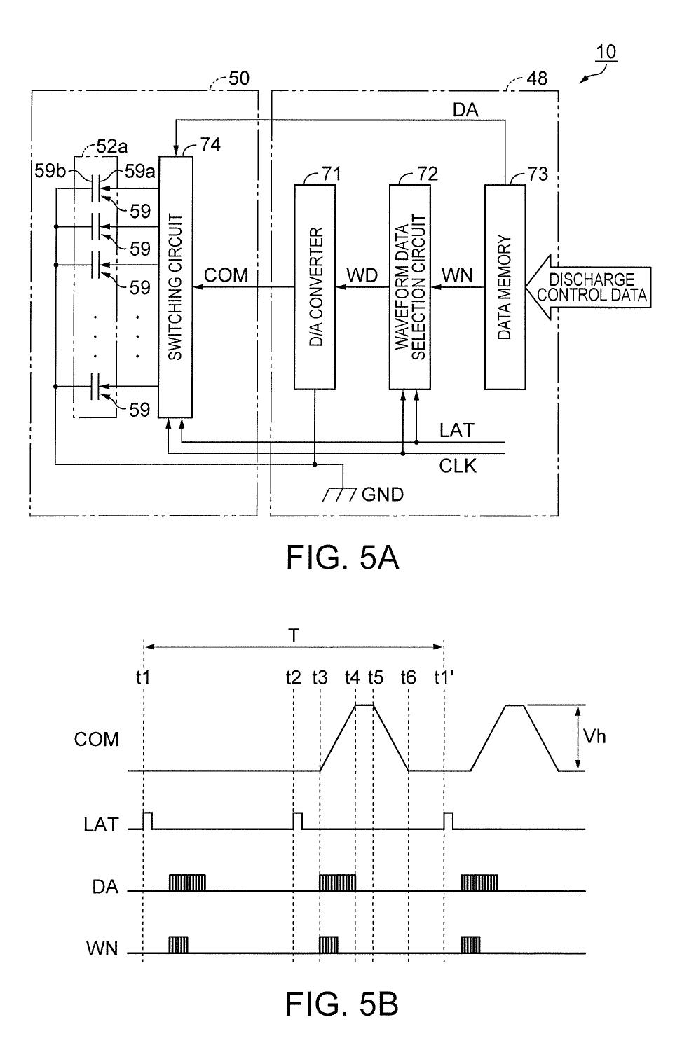

Next, the drive-control of the droplet discharge head is described with reference to FIGS. 5A and 5B. FIGS. 5A and 5B are views explaining the control of the droplet discharge head. FIG. 5A is a diagram showing the electrical control of the droplet discharge head. FIG. 5B is a timing chart of a driving signal and control signals.

As shown in FIG. 5A, the head driver 48 includes: a D/A converter (hereinafter, referred to as a DAC) 71 generating a driving signal COM that controls the droplet discharge head 50; a waveform data selection circuit 72 internally having a storage memory for slew rate data (hereinafter, referred to as a waveform data WD) of the driving signal COM (COM line) generated by the DAC 71; and a data memory 73 for storing discharge control data transmitted from the high-order computer 11 through the P-CON 44. The driving signal COM generated by the DAC 71 is outputted to the COM line.

Each droplet discharge head 50 includes a switching circuit 74 that turns on/off of an application of the driving signal COM to the vibrator 59 provided to the nozzle 52. In the nozzle 52, the electrode 59b, which is one electrode of the vibrator 59, is coupled to a ground line (GND) of the DAC 71. The electrode 59a (hereinafter, referred to as a segment electrode 59a), which is the other electrode of the vibrator 59, is electrically coupled to the COM line through the switching circuit 74. In addition, a clock signal (CLK) and a latch signal (LAT) corresponding to each discharge timing are inputted to the switching circuit 74 and the waveform data selection circuit 72.

The data memory 73 stores a discharge data DA prescribing the application (on/off) of the driving signal COM to the vibrator 59 at every driving timing of the droplet discharge head 50 and a waveform number data WN prescribing the kind of waveform data WD inputted to the DAC 71.

In the structure described above, the drive-control related to discharge timing is carried out as follows. As shown in FIG. 5B, in a period of from a timing t1 to a timing t2, the discharge data DA and the waveform number data WN are converted into serial signals, and respectively transmitted to the switching circuit 74 and the waveform data selection circuit 72. Then, each data is latched at the timing t2 so that the segment electrodes 59a of the vibrators 59 related to the discharge (ON) are coupled to the COM line. The waveform data WD of the driving signal generated by the DAC 71 is set.

In a period of from a timing t3 to a timing t5, the driving signal COM is generated in sequential steps of a potential rise, a potential retention, and a potential fall in accordance with the waveform data WD set at the timing t2. Then, the generated driving signal COM is supplied to the vibrator 59 coupled to the COM line so as to control the volume (pressure) of the cavity 55 communicating with the nozzle 52. Here, a potential Vh serving as a rise component at the timing t3 expands the cavity 55, and plays a role of drawing the liquid body into the cavity 55. The potential Vh serving as a fall component at the timing t5 contracts the cavity 55, and plays a role of pushing out the liquid body from the nozzle 52 to discharge it.

Accordingly, changing the generated driving signal COM enables discharge conditions such as the discharge amount and the discharge speed of the liquid body to be controlled. Specifically, the discharge amount of the liquid body discharged from the nozzle 52 can be increased or decreased by increasing or decreasing the potential Vh while the discharge speed of the liquid body can be changed by changing a slope of the potential Vh serving as the fall component at the timing t5. In addition, an interval (a period T) of discharging the liquid body from the nozzle 52 can be changed by changing time of the period T, which is time from the timing t1 to the timing t1′.

Liquid Body Discharging Method and Color Filter Manufacturing Method

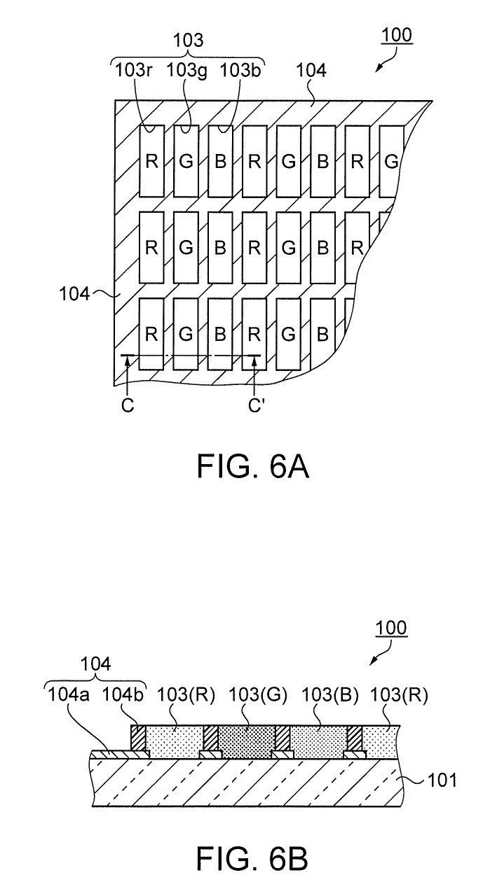

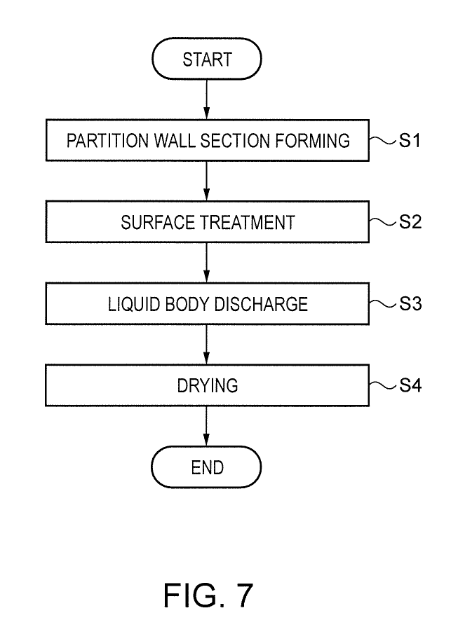

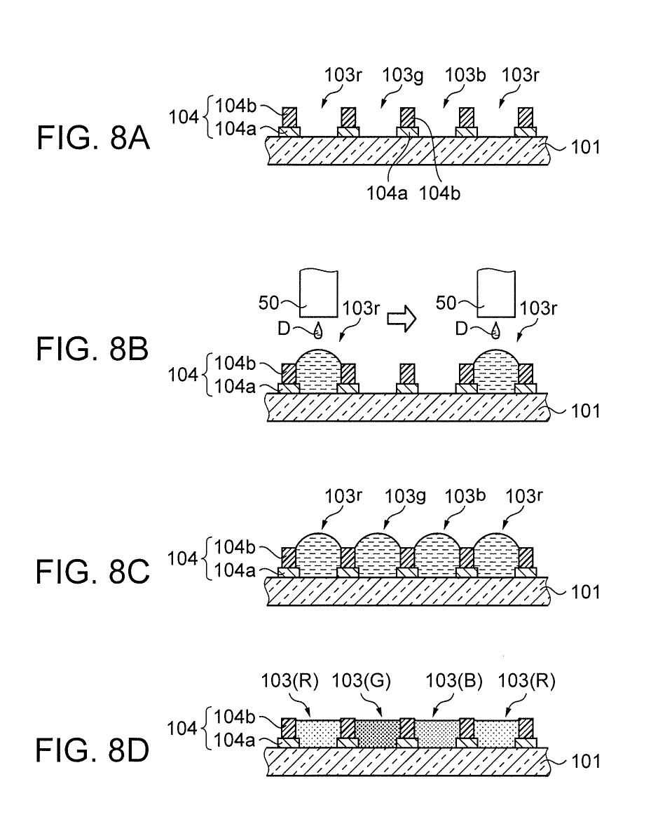

A method for manufacturing a color filter employing the method for discharging a liquid body of the embodiment is described with reference to FIGS. 6A to 8D. FIGS. 6A and 6B are schematic views showing a color filter. FIG. 6A is a schematic plan view of the color filter. FIG. 6B is a sectional view taking along the line C-C′ in FIG. 6A. FIG. 7 is a flow chart showing manufacturing steps of the color filter. FIGS. 8A to 8D are sectional views schematically showing manufacturing steps of the color filter.

As shown in FIGS. 6A and 6B, a color filter 100 has colored layers 103, which are filter elements of three colors of red (R), green (G), and blue (B), on a substrate 101 made of, for example, transparent glass. The colored layer 103 includes film forming regions 103r, 103g, and 103b, which are partitioned by a partition wall section 104 in a matrix, and each of which has a rectangular shape and serves as a region to which a liquid body is discharged (hereinafter, referred to as a discharged region). The color filter 100 of the embodiment is what is called a color filter of a stripe type. In the color filter 100, the colored layers 103 of each color are arranged in a linear manner.

As shown in FIG. 6B, the partition wall section 104 has a two-layer structure composed of a first partition wall section 104a and a second partition wall section 104b. The first partition wall section 104a is, for example, a thin film made of metal such as Cr and Al, and has a light shielding property. The second partition wall section 104b is, for example, made of a resin material. The structure is not limited to the two-layer structure. The partition wall section 104 may be made of a resin material containing a component having a light shielding property as a single-layer structure.

The colored layer 103 is made of a transparent resin material containing a coloring material. In the embodiment, the color filter 100 is manufactured by using the liquid body discharge device 10.

As shown in FIG. 7, the method for manufacturing the color filter 100 of the embodiment basically includes the following four steps. A partition wall section forming step (step S1) to form the partition wall section 104; a surface treatment step (step S2) to perform a surface treatment on the surface of the substrate 101 on which the partition wall section 104 has been formed; a discharge step (step S3) to discharge a liquid body containing a colored layer forming material; and a drying step (step S4) to dry the discharged liquid body to form the colored layers 103.

In the step S1 of FIG. 7, a thin film of metal such as Cr and Al is first formed on the surface of the substrate 101. Examples of film forming methods include a vacuum vapor deposition method, and a sputtering method. The film is formed, for example, with a thickness of about 0.1 μm so as to have a light shielding property. The metal thin film is patterned by photolithography to form the first partition wall section 104a defining opening regions as shown in FIG. 8A. Then, a photosensitive resin is applied with a thickness of about 2 μm to cover the first partition wall section 104a. The resin is patterned by photolithography to form the second partition wall section 104b on the first partition wall section 104a. As a result, the film forming regions 103r, 103g, and 103b are formed on the substrate 101 as the opening regions each having a rectangular shape. Then, the method proceeds to the step S2.

In the step S2 of FIG. 7, the surface of the substrate 101 is subjected to a lyophilic treatment so that the discharged liquid body lands on, and then wets and spreads in the film forming regions 103r, 103g, and 103b in a liquid body discharge step, which is described later. In addition, at least the upper surface portion of the second partition wall section 104b is subjected to a lyophobic treatment so that part of the discharged liquid body landed on the second partition wall section 104b flows in the film forming regions 103r, 103g, and 103b.

As for the surface treatment, plasma processings with O₂ and a fluoric gas as a processing gas are carried out on the substrate 101 on which the partition section 104 has been formed. That is, the film forming regions 103r, 103g, and 103b are subjected to the lyophilic treatment, and then the upper surface of the second partition wall section 104b made of a photosensitive resin is subjected to the lyophobic treatment. If the second partition wall section 104b is made of a material having lyophobicity, the latter treatment can be omitted. Then, the method proceeds to the step S3.

In the step S3 of FIG. 7, the substrate 101 having surface-treated is placed on the stage 5 of the droplet discharge device 10 shown in FIG. 1. Then, liquid bodies that have three different colors containing different colored layer forming materials are discharged from the droplet discharge heads 50 of the head unit 9 shown in FIG. 3. Specifically, as shown in FIGS. 8B and 8C, liquid bodies of three colors are discharged from the nozzles 52 of the droplets discharge heads 50 as the droplets D to the respective desired film forming regions 103r, 103g, and 103b in synchronization with the relative movement of the substrate 101 and the droplet discharge heads 50 in the main scan direction. The discharge amounts of the liquid bodies discharged to the film forming regions 103r, 103g, and 103b are controlled by proper control signals sent from the CPU 41 of the controller 4 to the head driver 48. The CPU 41 sends the signals based on discharge data that sets in advance, for the every main scan, a selection pattern of the nozzles 52, the number of discharges of the droplet D, and the like that are selected for each of the film forming regions 103r, 103g, and 103b. As a result, the liquid bodies each having a desired amount are discharged to the respective film forming regions 103r, 103g, and 103b. The method for discharging a liquid body is described later in detail. Then, the method proceeds to the step S4.

In the step S4 of FIG. 7, as shown in FIG. 8D, the solvent components are evaporated from the discharged liquid bodies on the substrate 101 so as to form the colored layers 103 made of the colored layer forming materials. In the embodiment, the substrate 101 is placed and reduced-pressure dried, in a reduced-pressure drying device capable of performing a drying processing while maintaining steam pressure of solvent constant, so as to form the colored layers 103 of three colors of R, G, and B. In this regard, the colored layer 103 may be formed by repeating three times a step of discharging the liquid body of one of the colors and drying it. In the step S3, the film thickness of the colored layer 103 is set every color, and is not necessarily set to the same thickness for the three colors. The liquid bodies may be discharged to the respective film forming regions 103r, 103g, and 103b with respective required amounts based on the required film thicknesses.

The size of the substrate 101, in which the color filter 100 is formed, depends on that of a display device using the substrate 101. Even though the display devices having the same size, one having pixels arranged at a high density requires the color filter 100 to arrange the colored layers 103 at a high density. As a method for producing the color filters 100 more efficiently, in general, the color filters 100 are arranged in multiple numbers on a mother substrate B having an area larger than that of the substrate 101 (a multi-piece substrate arrangement method). The size of the mother substrate B dominates the size of the color filter 100 from an efficient area point of view. If the color filter 100, which has a size inefficient from the area point of view, is arranged in multiple numbers, causing the mother substrate B to have spaces. It can be useful that the color filter 100 having another size is arranged in the space in multiple numbers for utilizing the mother substrate B without any wastes.

When the color filters 100 having different sizes are arranged on the mother substrate B, the film forming regions 103r, 103g, and 103b having different sizes may be mixedly formed on the mother substrate B. As described above, the arrangement of the droplets in the film forming regions 103r, 103g, and 103b is determined by an arrangement interval (the nozzle pitch P) of the nozzles 52 in the sub scan direction and discharge timing in the main scan. When the sizes of the film forming regions 103r, 103g, and 103b each having a rectangular shape are different on the mother substrate B, the number of nozzles 52 that faces the film forming regions 103r, 103g, and 103b having a smaller size is limited.

The method for manufacturing the color filter 100 by using the method for discharging a liquid body of the embodiment provides a preferable method for discharging a liquid body based on the sizes of the film forming regions 103r, 103g, and 103b on the mother substrate B. The details are described in the following examples.

### First Example

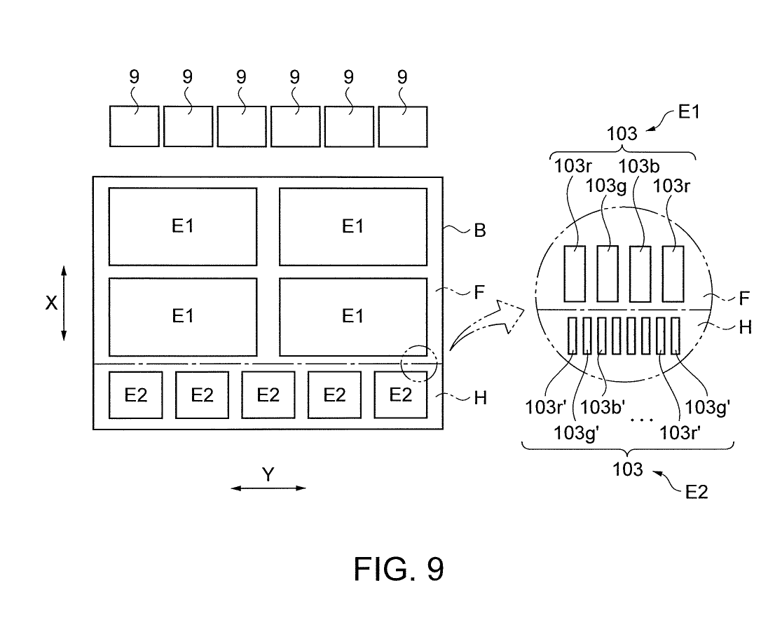

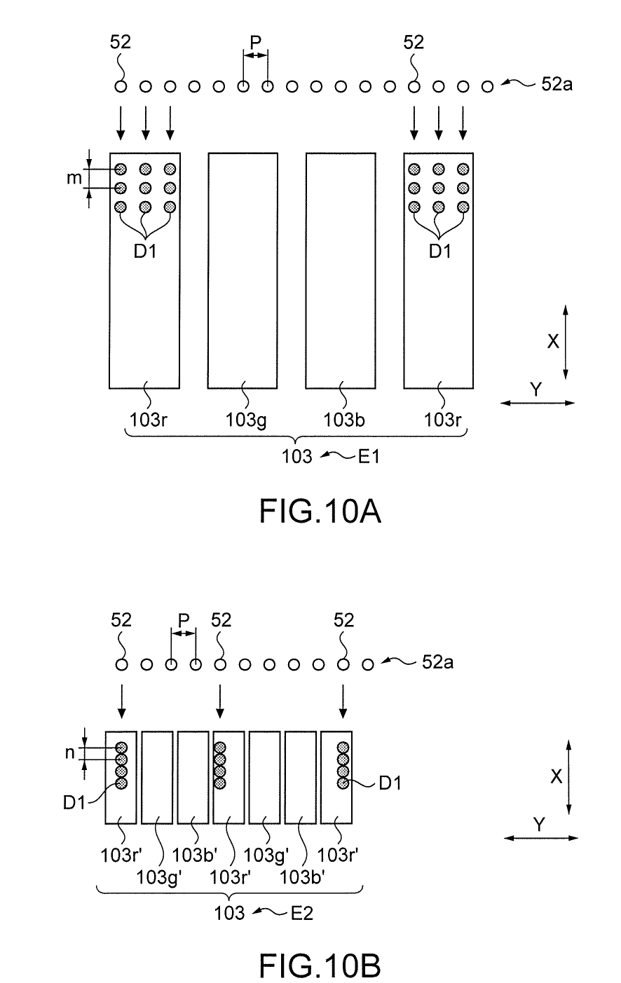

A method for manufacturing a color filter of a first example is described with reference to FIG. 9 and FIGS. 10A and 10B. FIG. 9 is a schematic plan view showing a relative arrangement between the head unit and the mother substrate in a discharge step of a liquid body. FIGS. 10A and 10B are schematic plan views showing an arrangement of droplets in the liquid body discharge step. The X direction and the Y direction shown in FIG. 9 and FIGS. 10A and 10B respectively indicate the same direction as the X direction and the Y direction in FIG. 1 indicate.

As shown in FIG. 9, the mother substrate B includes first panels E1 and second panels E2. The first panel E1 is arranged in multiple numbers (in this case, four) in a matrix along a long side at an upper part and a short side of the mother substrate B. The second panel E2 is arranged in multiple numbers (in this case, five) along a long side at a lower part of the mother substrate B. Here, the second panel E2 has an area smaller than that of the first panel E1. In the mother substrate B, the region in which four first panels E1 are arranged is referred to as a region F while the region in which five second panels E2 are arranged is referred to as a region H.

In the first panel E1, the film forming regions 103r, 103g, and 103b, each having a rectangular shape and serving as a first discharged region, are arranged in multiple numbers in a matrix. Likewise, in the second panel E2, the film forming regions 103r′, 103g′, and 103b′, each having a rectangular shape and serving as a second discharged region, are arranged in multiple numbers in a matrix. Here, the area of the film forming region 103r′ is smaller than that of the film forming region 103r. In the same manner, the areas of the film forming regions of 103g′ and 103b′ are respectively smaller than those of the film forming regions 103g, and 103b. The film forming region 103r and the film forming region 103r′ are arranged in a same stripe direction in which the liquid body of the same kind (color) is discharged. In the same manner, the film forming regions 103g and 103g′ as well as the film forming regions 103b and 103b′ are arranged in the same stripe directions of the respective colors. Desired liquid bodies are discharged to respective film forming regions with desired amounts to form the colored layers 103.

In the examples, the mother substrate B is placed on the stage 5 of the liquid body discharge device 10 shown in FIG. 1. Specifically, the mother substrate B is set on the stage 5 so that the long side of the mother substrate B is approximately in parallel with the head units 9 arranged in the Y direction. The droplet discharge heads 50 mounted to the head unit 9 discharge liquid bodies to the mother substrate B while the stage 5 moves in the X direction.

In this case, the short side direction of the film forming regions 103r, 103g, 103b, 103r′, 103g′, and 103b coincides with the Y direction. The nozzle line 52a provided in the droplet discharge head 50 is also disposed so as to coincide with the Y direction. As a result, as shown in FIGS. 10A and 10B, the nozzle line 52a having the nozzles 52 is disposed in the short side direction of the film forming regions 103r, 103g, 103b, 103r′, 103g′, and 103b′.

As shown in FIG. 10A, in the Y direction, for example, three nozzles 52 are allocated to the film forming region 103r to which a liquid body of red color is discharged. The nozzles 52 (three nozzles) discharge droplets D1. Thus, three droplets D1 are landed on the film forming region 103r. The landed droplets D1 wet and spread in the film forming region 103r. In the X direction, the droplets D1 can be landed in the film forming region 103r at predetermined positions with a constant discharge interval m by controlling discharge timing. In the Y direction, the landed positions in each film forming region 103r may differ because of a relation between the arrangement pith of the film forming regions 103r in the Y direction and the nozzle pitch P. Likewise, the desired liquid bodies are respectively discharged in the film forming regions 103g and 103b in the first panel E1 with three droplets D1 each.

As shown in FIG. 10B, in the main scan, for example, the one nozzle 52 is allocated to the film forming region 103r′ having an area smaller than that of the film forming region 103r. The nozzle 52 allocated to the film forming region 103r′ discharges droplets D1 in the X direction. Thus, one droplet D1 is landed on each film forming region 103r. In the X direction, the droplets D1 can be landed at predetermined positions with a discharge interval n smaller than the discharge interval m (m>n) in the film forming region 103r′ by controlling discharge timing. In the Y direction, the landed positions in each film forming region 103r′ may differ because of a relation between the arrangement pith of the film forming regions 103r′ in the Y direction and the nozzle pitch P. Likewise, the desired liquid bodies are respectively discharged in the film forming regions 103g′ and 103b′ in the second panel E2 with one droplet D1 each.

The discharge intervals m and n can be respectively set to different values by changing the relative moving speed in the X direction between the head unit 9 and the stage 5 with the substrate moving mechanism 20 shown in FIG. 4. Here, the head 9 includes the droplet discharge heads 50 each having the nozzle line 52a, and the stage 5 places the mother substrate B thereon as shown in FIG. 1. Specifically, the relative moving speed in the X direction between the nozzle line 52a and the mother substrate B in the region H of the mother substrate B is set slower than that in the region F of the mother substrate B. That is, the discharge interval n in the X direction in the region H, i.e., in the film forming region 103r′ can be set narrower than the discharge interval m in the X direction in the region F, i.e., in the film forming region 103r. In other words, a droplet applying density in the X direction in the film forming region 103r′ having a smaller area can be set larger than that in the film forming region 103r having a larger area.

The method can narrows the droplet landed intervals in the X direction in the film forming regions 103r′, 103g′, and 103b′ in which the number of nozzles 52 allocated to discharge liquid bodies thereto is limited since the regions have a small area. As a result, the supply amounts of the droplets D1 can be increased. That is, liquid bodies can be stably supplied with predetermined amounts. This stable supply can reduce that liquid bodies are eccentrically landed in the film forming regions 103r′, 103g′, and 103b′, enabling at least two kinds of thin films to be manufactured with stable quality. Consequently, the method can contribute to improve the productivity of color filters.

### Second Example

A method for manufacturing a color filter of a second example is described also with reference to FIG. 9 and FIGS. 10A and 10B. The second example differs from the first example in a method for adjusting the discharge interval m in the film forming region 103r as well as the discharge interval n in the film forming region 103r′. The same numeral is given to the same structure as the first example employs, and the description thereof is omitted.

In the second example, the discharge intervals m and n are respectively set different values by changing waveforms of a driving signal COM, shown in FIG. 5B, generated by the head driver 48 shown in FIG. 5A. Specifically, changing a period T of the driving signal COM varies discharge timing at which a liquid body is discharged from the nozzle 52. That is, with reference to FIG. 9, the period T of the driving signal COM in the region H in the mother substrate B is set shorter than that in the region F in the mother substrate B. The discharge interval n in the X direction in the region H, i.e., in the film forming region 103r′ can be set narrower than the discharge interval m in the X direction in the region F, i.e., in the film forming region 103r. In other words, a droplet applying density in the X direction in the film forming region 103r′ having a smaller area can be set larger than that in the film forming region 103r having a larger area.

The method can narrow the droplet landed intervals in the X direction in the film forming regions 103r′, 103g′, and 103b′ in which the number of nozzles 52 allocated to discharge liquid bodies thereto is limited since the regions have a small area. As a result, the supply amounts of the droplets D1 can be increased. That is, liquid bodies can be stably supplied with predetermined amounts. This stable supply can reduce that liquid bodies are eccentrically landed in the film forming regions 103r′, 103g′, and 103b′, enabling at least two kinds of thin films to be manufactured with stable quality. Consequently, the method can contribute to improve the productivity of color filters.

### Third Example

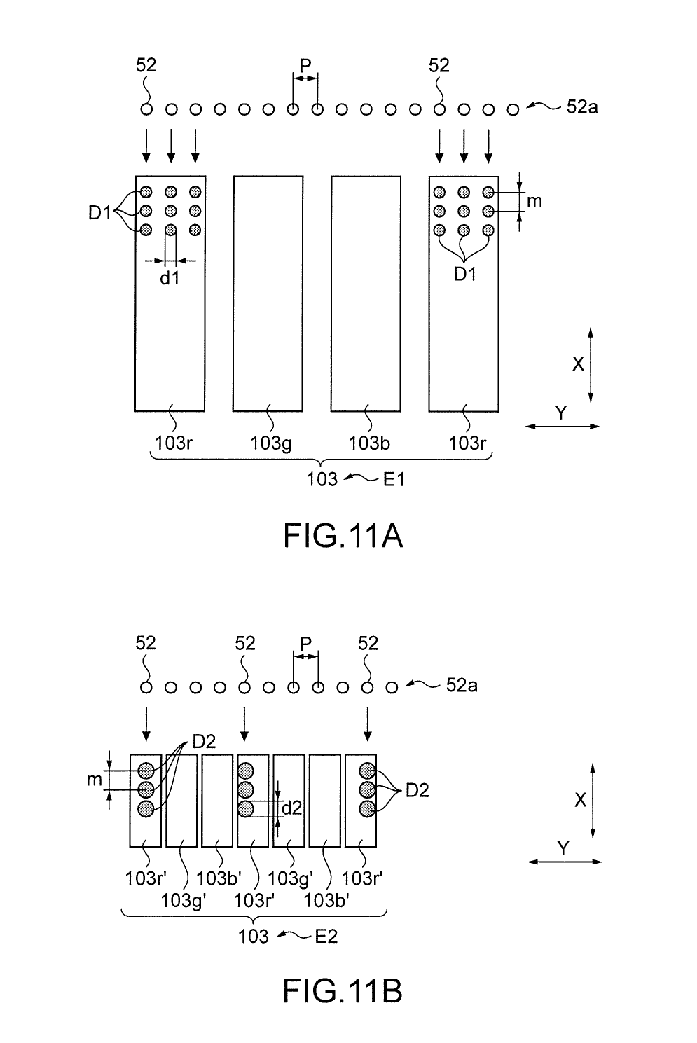

A method for manufacturing a color filter of a third example is described with reference to FIG. 9 and FIGS. 11A and 11B. FIGS. 11A and 11B are schematic plan views showing an arrangement of droplets in a liquid body discharge step of the third example. The same numeral is given to the same structure as the first example employs, and the description thereof is omitted.

In the third example, the mother substrate B shown in FIG. 9 is placed on the stage 5 of the liquid body discharge device 10 shown in FIG. 1 in the same manner as the second example. The droplet discharge heads 50 mounted to the head unit 9 discharge liquid bodies to the mother substrate B while the stage 5 moves in the X direction.

In this case, the short side direction of the film forming regions 103r, 103g, 103b, 103r′, 103g′, and 103b also coincides with the Y direction. The nozzle line 52a provided in the droplet discharge head 50 is also disposed so as to coincide with the Y direction. As a result, as shown in FIG. 11A, the nozzle line 52a having the nozzles 52 is disposed in the short side direction of the film forming regions 103r, 103g, 103b, 103r′, 103g′, and 103b′.

As shown in FIG. 11A, in the Y direction, for example, three nozzles 52 are allocated to the film forming region 103r to which a liquid body of red color is discharged. The nozzles 52 (three nozzles) discharge droplets D1. Thus, three droplets D1 are landed on the film forming region 103r. The landed droplets D1 wet and spread in the film forming region 103r. In the X direction, the droplets D1 can be landed in the film forming region 103r at predetermined positions with the constant discharge interval m by controlling discharge timing. Likewise, the desired liquid bodies are respectively discharged in the film forming regions 103g and 103b in the first panel E1 with three droplets D1 each.

As shown in FIG. 11B, in the main scan, for example, the one nozzle 52 is allocated to the film forming region 103r′ having an area smaller than that of the film forming region 103r. The nozzle 52 allocated to the film forming region 103r′ discharges the droplets D2 in the relative movement in the X direction. In this discharge, the discharge amount of the liquid body discharged from the nozzle 52 is set larger than that of the discharge shown in FIG. 11A while the discharge interval of the droplets D2 in the X direction is the same as the discharge interval m in the film forming region 103r. Therefore, as shown in FIG. 11B, a landed diameter d2 of the droplet D2 landed on the film forming region 103r′ is larger than a landed diameter d1 of the droplet D1 landed on the film forming region 103r. Likewise, the desired liquid bodies are respectively discharged in the film forming regions 103g′ and 103b′ in the second panel E2 as droplets D2 each.

The amount of the droplet D discharged from the nozzle 52 (discharge amount) can be increased or decreased by increasing or decreasing the potential Vh of the driving signal COM shown in FIG. 5B. In the examples, a potential Vh2 is set higher than a potential Vh1 where the potential Vh2 is the potential of the driving signal COM applied to the nozzle 52 when a liquid body is discharged to the film forming region 103r′ while the potential Vh1 is the potential of the driving signal COM applied to the nozzle 52 when a liquid body is discharged to the film forming region 103r. As a result, the amount of the droplet D2 discharged to the film forming region 103r′ is larger than the amount of the droplet D1 discharged to the film forming region 103r.

The method can increase the amount of the droplet D2 when the droplets D2 are discharged in the film forming regions 103r′, 103g′, and 103b′ in which the number of nozzles 52 allocated to discharge liquid bodies thereto is limited since the regions have a small area. As a result, the supply amounts of the droplets D2 can be increased. That is, liquid bodies can be stably supplied with predetermined amounts. This stable supply can reduce that liquid bodies are eccentrically landed in the film forming regions 103r′, 103g′, and 103b′, enabling at least two kinds of thin films to be manufactured with stable quality. Consequently, the method can contribute to improve the productivity of color filters.

### Fourth Example

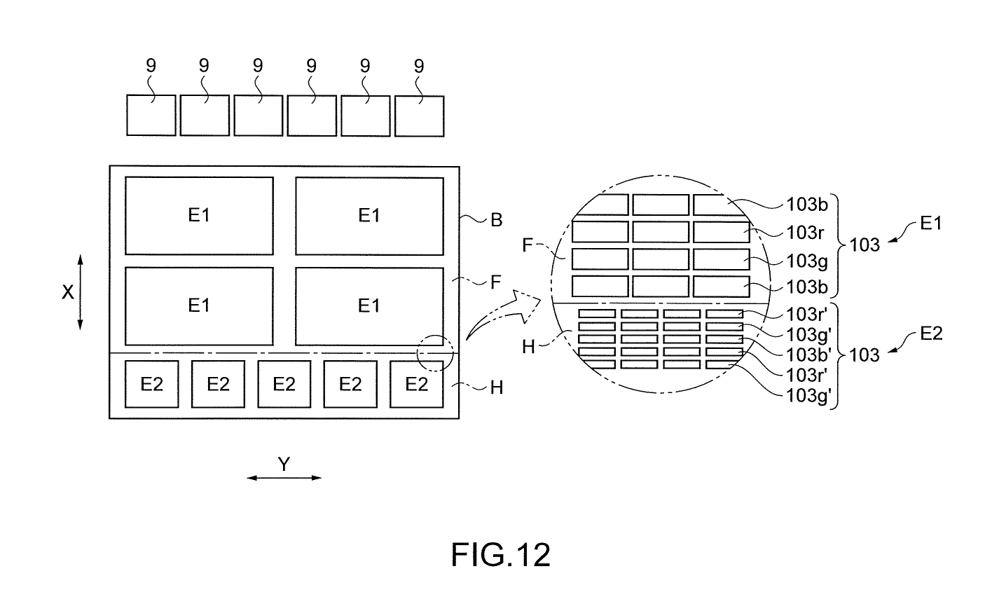

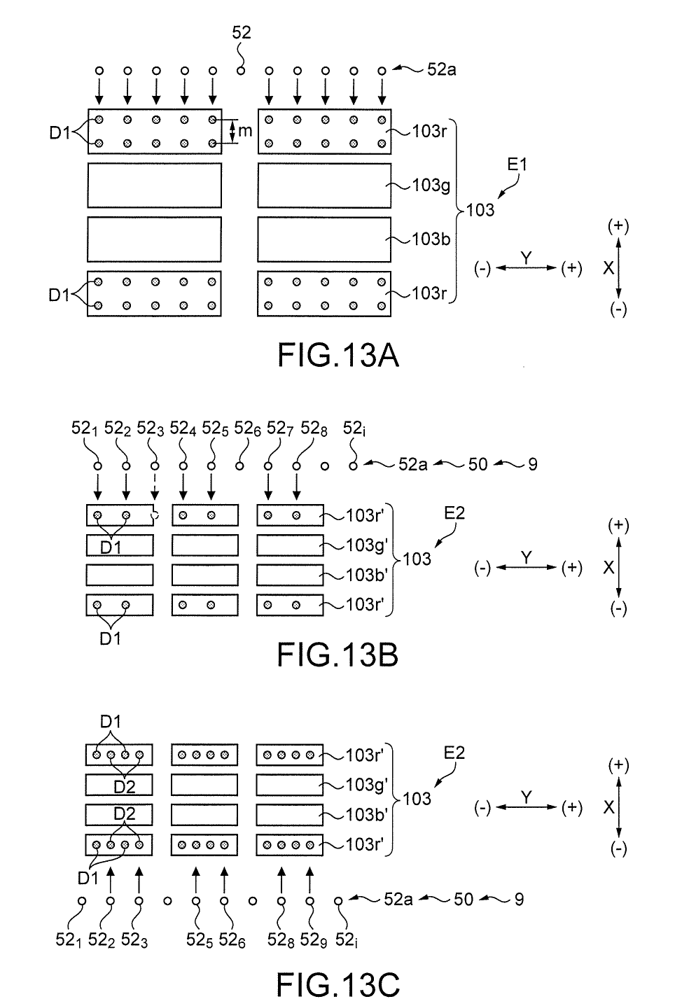

A method for manufacturing a color filter of a fourth example is described with reference to FIG. 12 and FIGS. 13A, 13B, and 13C. FIG. 12 is a schematic plan view showing a relative arrangement between the head unit and the mother substrate in a discharge step of a liquid body in the fourth example. FIGS. 13A to 13C are schematic plan views showing an arrangement of droplets in the liquid body discharge step of the fourth example. The same numerals are given to the same structures as the first to third examples employ, and the descriptions thereof are omitted.

As shown in FIG. 12, the mother substrate B of the fourth example includes first panels E1 and second panels E2 in the same manner as the above examples. The first panel E1 is arranged in multiple numbers (in this case, four) in the region F of the mother substrate B. The second panel E2 is arranged in multiple numbers (in this case, five) in the region H of the mother substrate B. Here, the second panel E2 has an area smaller than that of the first panel E1.

In the first panel E1, the film forming regions 103r, 103g, and 103b, each having a rectangular shape and serving as the first discharged region, are arranged in multiple numbers in a matrix. Likewise, in the second panel E2, the film forming regions 103r′, 103g′, and 103b′, each having a rectangular shape and serving as the second discharged region, are arranged in multiple numbers in a matrix. Here, the area of the film forming region 103r′ is smaller than that of the film forming region 103r. In the same manner, the areas of the film forming regions of 103g′ and 103b′ are respectively smaller than those of the film forming regions 103g and 103b. The film forming region 103r and the film forming region 103r′ are arranged in a same stripe direction in which the liquid body of the same kind (color) is discharged. In the same manner, the film forming regions 103g and 103g′ as well as the film forming regions 103b and 103b′ are arranged in the same stripe directions of the respective colors. Desired liquid bodies are discharged to respective film forming regions with desired amounts to form the colored layers 103.

In the example, the mother substrate B is placed on the stage 5 of the liquid body discharge device 10 shown in FIG. 1. Specifically, the mother substrate B is set on the stage 5 so that the long side of the mother substrate B is approximately in parallel with the head units 9 arranged in the Y direction. The droplet discharge heads 50 mounted to the head unit 9 discharge liquid bodies to the mother substrate B while the stage 5 moves in the X direction.

In this case, the long side direction of the film forming regions 103r, 103g, 103b, 103r′, 103g′, and 103b coincides with the Y direction. The nozzle line 52a provided in the droplet discharge head 50 is also disposed so as to coincide with the Y direction. As a result, as shown in FIG. 13A, the nozzle line 52a having the nozzles 52 is disposed in the long side direction of the film forming regions 103r, 103g, 103b, 103r′, 103g′, and 103b′.

As shown in FIG. 13A, in the Y direction, for example, five nozzles 52 are allocated to the film forming region 103r to which a liquid body of red color is discharged. The nozzles 52 (five nozzles) discharge droplets D1. Thus, five droplets D1 are landed on the film forming region 103r. In the X direction, the droplets D1 can be landed in the film forming region 103r at predetermined positions with the constant discharge interval m by controlling discharge timing. As a result, 10 droplets D1 are supplied to the film forming region 103r. The landed droplets D1 wet and spread in the film forming region 103r. Likewise, the desired liquid bodies are respectively discharged in the film forming regions 103g and 103b in the first panel E1 with 10 droplets D1 each. As described above, the film forming region 103r having a large area can be coated with a lot of the droplets D1.

In contrast, for supplying the droplets D to the film forming region 103r′ having an area smaller than that of the film forming region 103r, the number of nozzle 52 allocated to supply the droplets D thereto is limited because of a relation between the arrangement pith of the film forming regions 103r′ in the Y direction and the nozzle pitch P. For example, as shown in FIG. 13B, the nozzle line 52a includes a plurality of nozzles 52i (i is natural number and i≧1) and arranged in the long side of the film forming region 103r′. The width of the film forming region 103r′ in the long side direction is smaller than that of the film forming region 103r. When the liquid body of red is simultaneously discharged from three nozzles 52₁ to 52₃ to the film forming region 103r′, for example, the liquid body of red may be landed on an edge part of the film forming region 103r′ and mix in the film forming region 103g′. Because of this possibility, two nozzles 52₁ and 52₂ are used for the film forming region 103r′.

As shown in FIG. 13B, two droplets D1 are disposed with an interval therebetween in the film forming region 103r′ after a first-time discharge, in which the droplets D1 are discharged from the nozzles 52₁ and 52₂ while the mother substrate B is moved in the X (+) direction (in FIG. 13B) by the stage 5 shown in FIG. 1.

Then, the head unit 9 is slightly moved in the Y (−) direction (in FIG. 12B) by the head moving mechanism 30 shown in FIG. 1. As shown in FIG. 13C, the nozzles 52₂ and 52₃ are positioned in the film forming region 103r′ so that they face each other with the droplet D1 therebetween by adjusting a moving distance of the head unit 9. Then, the droplets D2 are discharged from the nozzles 52₂ and 52₃ while the mother substrate B is moved in the X (−) direction (in FIG. 13C) as a second-time discharge. As a result, the droplets D2 are disposed at a central part of the film forming region 103r′ in the X direction so that the droplets D1 and the droplets D2 are adjacent to each other. That is, the liquid body can be disposed in the film forming region 193r′ as the droplets D1 and D2 with shortened landed intervals in the Y direction by slightly moving the head unit 9 in the Y direction while the mother substrate B moves in the X direction and the liquid body is discharged from the nozzle 52i.

The method can narrow the droplet landed intervals in the Y direction in the film forming regions 103r′, 103g′, and 103b′ in which the number of nozzles 52 allocated to discharge liquid bodies thereto is limited since the regions have a small area. As a result, the supply amounts of the droplets D1 and D2 can be increased. That is, liquid bodies can be stably supplied with predetermined amounts. This stable supply can reduce that liquid bodies are eccentrically landed in the film forming regions 103r′, 103g′, and 103b′, enabling at least two kinds of thin films to be manufactured with stable quality. Consequently, the method can contribute to improve the productivity of color filters.

### Fifth Example

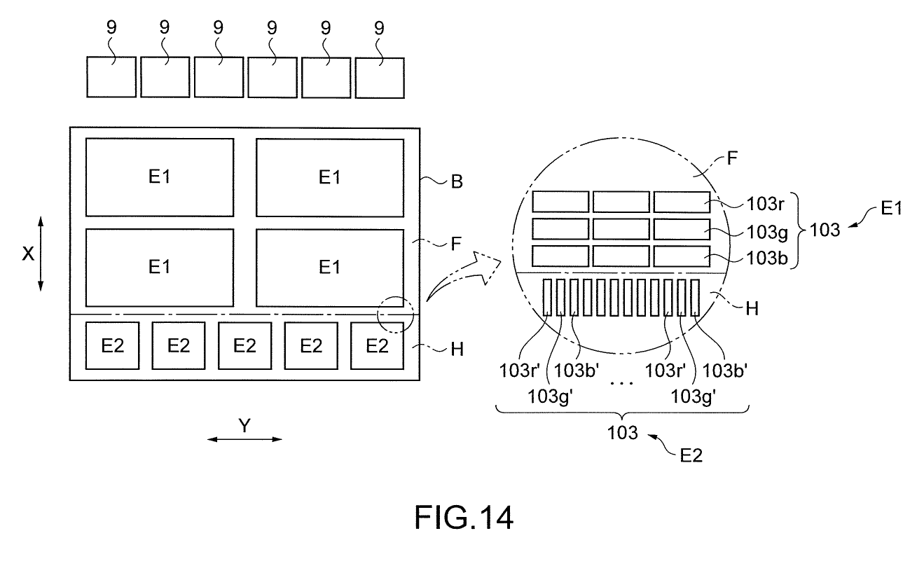

A method for manufacturing a color filter of a fifth example is described with reference to FIG. 14. FIG. 14 is a schematic plan view showing a relative arrangement between the head unit and the mother substrate in a liquid body discharge step of the fifth example. The same numerals are given to the same structures as the first to fourth examples employ, and the descriptions thereof are omitted.

As shown in FIG. 14, the mother substrate B includes first panels E1 and second panels E2 in the same manner as the above examples. The first panel E1 is arranged in multiple numbers (in this case, four) in a matrix along the long side at the upper part and the both short sides of the mother substrate B. The second panel E2 is arranged in multiple numbers (in this case, five) along the long side at the lower part of the mother substrate B. The second panel E2 has an area smaller than that of the first panel E1.

In the first panel E1, the film forming regions 103r, 103g, and 103b, each having a rectangular shape and serving as the first discharged region, are arranged in multiple numbers in a matrix. Likewise, in the second panel E2, the film forming regions 103r′, 103g′, and 103b′, each having a rectangular shape and serving as the second discharged region, are arranged in multiple numbers in a matrix. Here, the area of the film forming region 103r is larger than that of the film forming region 103r′. In the same manner, the areas of the film forming regions of 103g and 103b are respectively larger than those of the film forming regions 103g′, and 103b′. The film forming region 103r and the film forming region 103r′ are arranged so that both stripe directions in which the liquid body of the same kind (color) is discharged are perpendicular to each other. In the same manner, the film forming regions 103g and 103g′ as well as the film forming regions 103b and 103b′ are arranged so that the stripe directions of the respective colors are perpendicular to each other.

In the liquid body discharge step using the liquid body discharge device 10 shown in FIG. 1, the mother substrate B is positioned on the stage 5 so that the long side of the mother substrate B is approximately in parallel with the head units 9 arranged in the Y direction by the head moving mechanism 30. The droplet discharge heads 50 mounted to the head unit 9 discharge liquid bodies to the mother substrate B while the stage 5 moves in the X direction.

In this case, the long side direction of the film forming regions 103r, 103g, and 103b coincides with the Y direction. The long side direction of the film forming regions 103r′, 103g′, and 103b′ coincides with the X direction. The nozzle line 52a provided in the droplet discharge head 50 is disposed so as to coincide with the disposition direction of the head unit 9, i.e., the Y direction. Accordingly, the nozzle line 52a including the nozzles 52 is disposed in the long side direction of the film forming regions 103r, 103g, and 103b each having a rectangular shape. Therefore, the number of nozzles 52 that can discharge liquid bodies to the film forming regions 103r, 103g, and 103b is largely different from the number of nozzles 52 that can discharge liquid bodies to the film forming regions 103r′, 103g′, and 103b′. That is, the number of nozzles 52 that can discharge liquid bodies to the film forming regions 103r′, 103g′, and 103b′ is limited.

In the example, any of the methods for discharging a liquid body described in the first to fourth examples is applied to the region H in which the film forming regions 103r′, 103g′, and 103b′, to which the limited number of nozzles 52 is allocated to discharge liquid bodies, are formed. Specifically, a discharge condition by which liquid bodies are discharged from the nozzles 52 to the region F in which the film forming regions 103r, 103g, and 103b are formed, and a discharge condition by which liquid bodies are discharged from the nozzles 52 to the region H in which the film forming regions 103r′, 103g′, and 103b′ are formed are set to be different from each other.

When liquid bodies are supplied to the mother substrate B in which the film forming regions 103 having different sizes are mixedly formed and arranged in different directions, the method can stably supply the liquid bodies to each film forming region 103 with necessary amount by applying any of the methods for discharging a liquid body described in the first to fourth examples to the respective regions. As a result, problems such as uneven discharge amounts can be reduced. Consequently, the method enables at least two kinds of thin films to be manufactured with stable quality, contributing to improve the productivity of color filters.

### Sixth Example

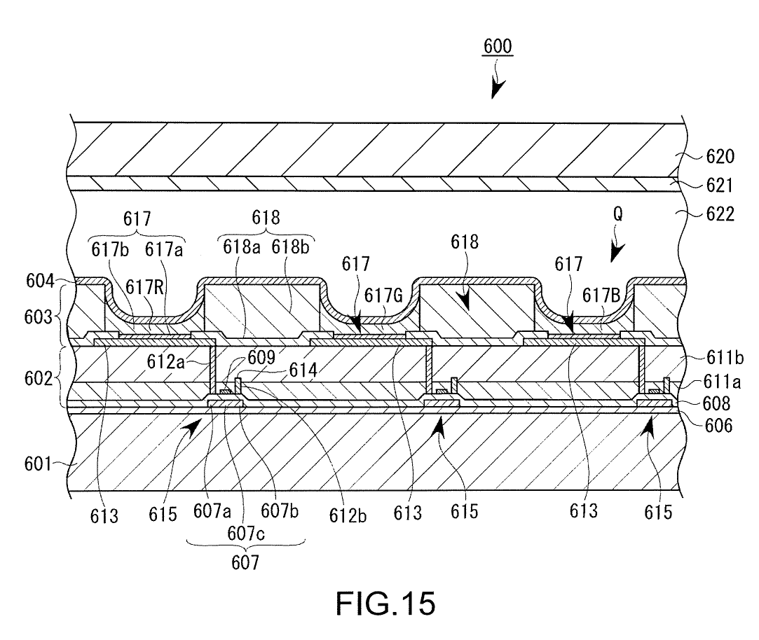

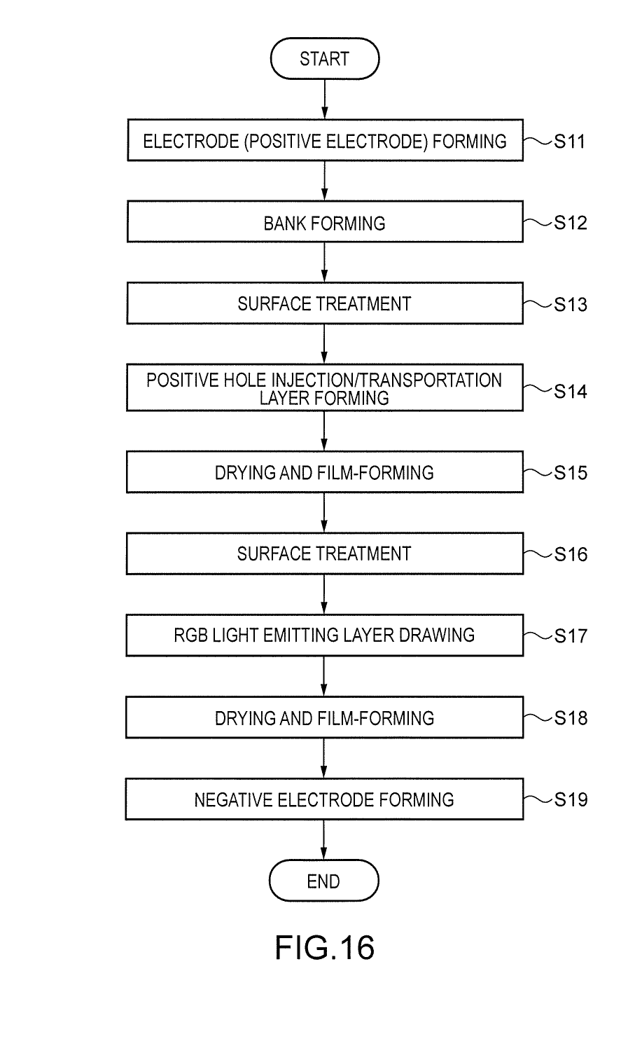

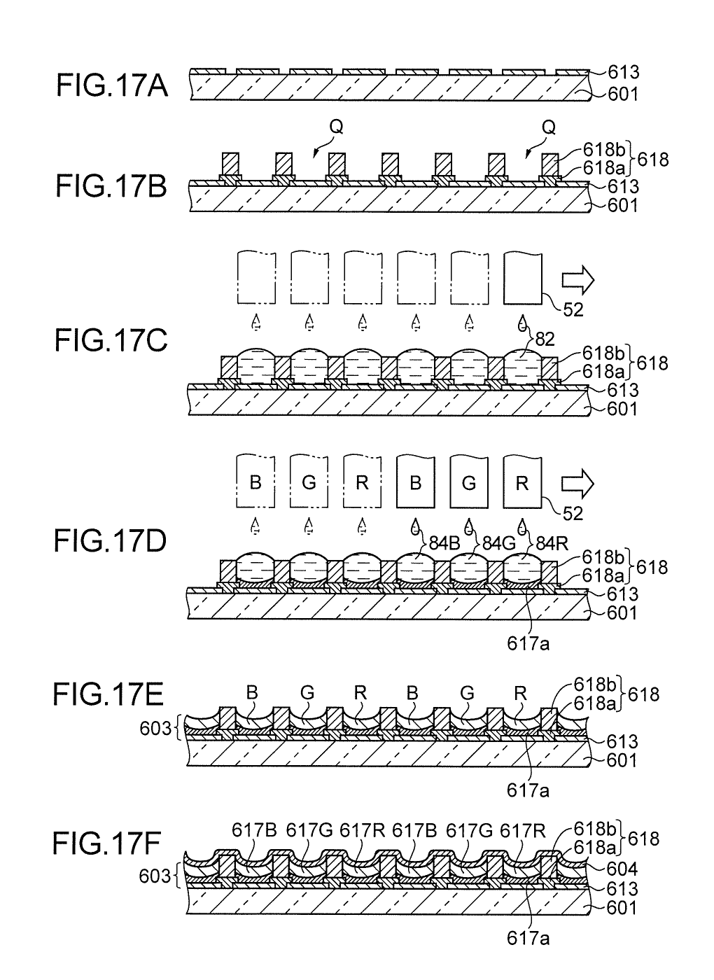

A method for manufacturing an organic EL device by using the method for discharging a liquid body is described with reference to FIG. 15, FIG. 16, and FIGS. 17A to 17F.

Organic EL Device

FIG. 15 is a sectional view schematically showing a structure of an essential part of an organic EL device. As shown in FIG. 15, an organic EL device 600, which is an electro-optical device, of the embodiment includes an element substrate 601 and a sealing substrate 620. The element substrate 601 includes a light emitting element section 603 serving as an organic EL element. The sealing substrate 620 is bonded to the element substrate 601 in a manner sealing a space 622 between the substrates 620 and 601. The element substrate 601 has a circuit element section 602 provided thereon. The light emitting element section 603 is formed on the circuit element section 602 and driven by the circuit element section 602. In the light emitting element section 603, light emitting layers 617R, 617G, and 617B of three colors are formed in discharged regions Q serving as their respective color element regions so as to be arranged in a stripe shape. A picture element is composed of three discharged regions Q corresponding to the light emitting layers 617R, 617G, and 617B of three colors. The picture element is disposed in a plurality of numbers in a matrix on the circuit element section 602 of the element substrate 601. In the organic EL device 600 of the embodiment, light emitted from the light emitting element section 603 is outputted to pass through the element substrate 601.

The sealing substrate 620, which is made of glass or metal, is bonded to the element substrate 601 with a sealing resin therebetween. A getter agent 621 is attached on the surface, which faces the element substrate 601, of the sealing substrate 620. The getter agent 621 absorbs water or oxygen entering the space 622 between the element substrate 601 and the sealing substrate 620 so as to prevent the light emitting element section 603 from being deteriorated by the water or the oxygen that enters the space 622. The getter agent 621, however, may be omitted.

The element substrate 601 has discharged regions Q on the circuit element section 602 as described above. The element substrate 601 is provided with banks 618 for partitioning the discharged regions Q, electrodes 613 formed in the discharged regions Q, and positive hole injection/transportation layers 617a layered on the electrodes 613. The light emitting element section 603 serves as a color element, and includes the light emitting layers 617R, 617G, and 617B, which are formed in the respective discharged regions Q with respective liquid bodies containing light emitting layer forming materials of three kinds. The bank 618 is composed of a lower layer bank 618a and an upper layer bank 618b that practically partition the discharged regions Q. The lower layer bank 618a is provided so as to protrude inside the discharged region Q. The lower layer bank 618a is made of an inorganic insulating material such as SiO₂ so as to prevent an electric short circuit caused by a direct contact of the electrodes 613 with the light emitting layers 617R, 617G, and 617B.

The element substrate 601 is made of a transparent substrate such as glass. On the element substrate 601, an underlayer protection film 606 made of a silicon oxide film is formed. Further, on the underlayer protection film 606, an island-like semiconductor film 607 made of polysilicon is formed. The semiconductor film 607 includes a source region 607a and a drain region 607b formed by high-concentration P ion implantation. A region where P is not ion-implanted serves as a channel region 607c. Additionally, a transparent gate insulation film 608 is formed that covers the underlying protection film 606 and the semiconductor film 607. On the gate insulation film 608 is formed a gate electrode 609 made of Al, Mo, Ta, Ti, W or the like. On the gate electrode 609 and the gate insulation film 608 are formed first and second interlayer insulation films 611a and 611b that are transparent. The gate electrode 609 is disposed at a position corresponding to the channel region 607c of the semiconductor film 607. Furthermore, contact holes 612a and 612b are formed that penetrate through the first and the second interlayer insulation films 611a and 611b to be respectively coupled to the source region 607a and the drain region 607b of the semiconductor film 607. On the second interlayer insulation film 611b, the electrode 613, which is transparent and made of indium tin oxide (ITO), is patterned into a predetermined shape (in an electrode formation step). The contact hole 612a is coupled to the electrode 613. The contact hole 612b is coupled to a power supply line 614. In this manner, in the circuit element section 602, driving thin film transistors 615 are formed that are connected to the electrodes 613. The circuit element section 602 includes a retention capacitance and a switching thin film transistor, although not shown in FIG. 15.

The light emitting element section 603 includes the electrodes 613 serving as a positive electrode, the positive hole injection/transportation layers 617a, the light emitting layers 617R, 617G and 617B (generally referred to as a light emitting layer 617b) and a negative electrode 604 layered to cover the upper layer banks 618b and the light emitting layers 617b. They are sequentially layered on the electrodes 613. Using a transparent material to form the negative electrode 604, the sealing substrate 620 and the getter agent 621 allows an emitted light to be outputted through the sealing substrate 620.

The organic EL device 600 includes a scan line (not shown) coupled to the gate electrode 609 and a signal line (not shown) coupled to the source region 607a. When a scan signal transmitted to the scan line allows the switching thin film transistor (not shown) to be turned on, a potential of the signal line at the point in time is retained by the retention capacitance. A status of the retention capacitance determines on or off of the driving thin film transistor 615. Then, an electric current flows from the power supply line 614 to the electrode 613 through the channel region 607c of the driving thin film transistor 615, and then, flows into the negative electrode 604 through the positive hole injection/transportation layer 617a and the light emitting layer 617b. The light emitting layer 617b emits light according to an amount of the current flowing therethrough. The light emitting mechanism of the light emitting element section 603 enables the organic EL device 600 to display desired characters, images, and the like.

Method for Manufacturing Organic EL Device

A method for manufacturing an organic EL display of the embodiment is described with reference to FIG. 16 and FIGS. 17A to 17F. FIG. 16 is a flowchart showing the method for manufacturing an organic EL display. FIGS. 17A to 17F are sectional views schematically showing the method for manufacturing an organic EL display. In FIGS. 16A to 16F, the circuit element section 602 formed on the element substrate 601 is not shown.

As shown in FIG. 16, the method for manufacturing an organic EL display includes a step of forming the electrode 613 at a position corresponding to the plurality of the discharged regions Q of the element substrate 601 and a bank (partition wall section) forming step in which the lower layer bank 618a is formed so that a part thereof overlaps with the electrode 613 and then the upper layer bank 618b is formed on the lower layer bank 618a so as to practically partition the discharged regions Q. Additionally, the method includes a step of performing a surface treatment on the discharged regions Q partitioned by the upper layer bank 618b, a step of discharge-drawing the positive hole injection/transportation layer 617a by applying a liquid body including a positive hole injection/transportation layer material to the discharged regions Q, and a step of drying the discharged liquid body to film-form the positive hole injection/transportation layer 617a. The method also includes a step of performing a surface treatment on the discharged regions Q in which the positive hole injection/transportation layers 617a are formed, a color element drawing step in which the light emitting layer 617b is discharge-drawn by applying three kinds of liquid bodies including light emitting layer forming materials as a color element forming material on the surface treated discharged regions Q, and a step of drying the discharged three kinds of the liquid bodies to film-form the light emitting layers 617b. Further, the method includes a step of forming the negative electrode 604 to cover the upper banks 618b and the light emitting layers 617b. The liquid bodies are applied to the discharged regions Q by using the liquid body discharge device 10.

A step S11 of FIG. 16 is a step of forming an electrode (a positive electrode). In the step S11, as shown in FIG. 7A, the electrodes 613 are formed at positions corresponding to the discharged regions Q of the element substrate 601 on which the circuit element section 602 has been formed. As a formation method, for example, a transparent electrode film made of a transparent electrode material such as ITO is formed on a surface of the element substrate 601 by a sputtering method or a vapor deposition method in a vacuum. Thereafter, the electrode film is etched by photolithography, leaving necessary parts to form the electrodes 613. Alternatively, the following manner may be employed. The element substrate 601 is covered with a photoresist. Then, the resist is exposed and developed to open regions in which the electrodes 613 are to be formed. Then, a transparent electrode film made of ITO, for example, is formed in the openings. Thereafter, remaining photo resist is removed. Then, the method proceeds to a step S12.

The step S12 of FIG. 16 is a step of forming a bank (a partition wall section). In the step S12, as shown in FIG. 7B, the lower layer bank 618a is formed so as to cover a part of the electrode 613 of the element substrate 601. The lower layer bank 618a is made of SiO₂ (silicon dioxide) that is an inorganic insulating material. The lower layer bank 618a is formed by the following manner as an example. The surfaces of the electrodes 613 are masked with a resist or the like so as to correspond to the light emitting layers 617b, which are formed later. Then, the element substrate 601 having been masked is put into a vacuum apparatus. In the apparatus, the lower banks 618a are formed by sputtering or vacuum deposition with SiO₂ as the target or the evaporation material. The masking made of the resist or the like is removed later. Since the lower layer bank 618a is made of SiO₂, it has a sufficient transparency if the film thickness is 200 nm or less. Thus, although the positive hole injection/transportation layers 617a and the light emitting layers 617b are layered later, light is emitted without being hindered.

Next, the upper layer bank 618b is formed on the lower layer bank 618a so as to practically partition the discharged regions Q. Preferably, the upper layer bank 618b is made of a material that is durable against the solvents of three kinds of liquid bodies 84R, 84G and 84B containing light emitting layer forming materials described later. More preferably, the upper layer bank 618b is made of an organic material such as an acryl resin, an epoxy resin and a photosensitive polyimide that can be changed to tetrafluoroethylene by a plasma processing using a fluoric gas as a processing gas. The upper layer bank 618b is formed by the following manner as an example. The photosensitive organic material is applied by roll coating or spin coating on a surface of the element substrate 601 on which the lower layer bank 618a has been formed. Then, the material is dried so as to form a photosensitive resin layer having a thickness of approximately 2 μm. Then, a mask having openings each having a size corresponding to that of each discharged region Q is opposed to the element substrate 601 at a predetermined position. Then, the applied material is exposed and developed so as to form the upper layer bank 618b. Accordingly, the bank 618 that includes the lower layer bank 618a and the upper layer bank 618b is formed as a partition wall section. Then, the method proceeds to a step S13.

The step S13 of FIG. 16 is a step of performing a surface treatment on the discharged regions Q. In the step S13, first, the surface of the element substrate 601 on which the banks 618 are formed is plasma processed by using an O₂ gas as a processing gas. This plasma process activates the surfaces of the electrodes 613, the surfaces of the protruded portions of the lower layer banks 618a and the surfaces (including the wall surfaces) of the upper layer banks 618b as a lyophilic treatment. Next, the surface of the element substrate 601 is plasma processed by using a fluoric gas such as CF₄ as a processing gas. The fluoric gas reacts only with the surfaces of the upper layer banks 618b made of the photosensitive resin which is an organic material, providing lyophilicity to the surfaces of the upper layer banks 618b. Then, the method proceeds to a step S14.

The step S14 of FIG. 16 is a step of forming the positive hole injection/transportation layer. In the step S14, as shown in FIG. 17C, a liquid body 82 containing a positive hole injection/transportation layer forming material is applied to the discharged regions Q. A method for applying the liquid body 82 uses the liquid body discharge device 10 described above. The liquid body 82 discharged from the liquid droplet discharge heads 50 lands as droplets and then the droplets wet and spread on the electrodes 613 of the element substrate 601. The liquid body 82 is discharged as droplets of a required amount corresponding to an area of the discharged region Q, and is disposed in the discharged region Q with a raised surface formed by surface tension. Since one kind of the liquid body 82 is discharged so as to draw a pattern by the liquid body discharge device 10, the discharge and drawing can be conducted by at least one time performing a main scan. Then, the method proceeds to a step S15.

The step S15 in FIG. 16 is a step of drying and film-forming. In the step S15, the element substrate 601 is heated, for example, by a lamp annealing method to dry and remove a solvent component of the liquid body 82, whereby the positive hole injection/transportation layers 617a are formed in regions partitioned by the lower layer banks 618a of the electrodes 613. In the embodiment, the positive hole injection/transportation layers are made of polyethylene dioxy thiophene (PEDOT). In this case, the positive hole injection/transport layers 617a made of a single material are formed in the discharged regions Q. However, the material for the positive hole injection/transportation layer 617a may be changed every discharged region Q corresponding to the material for forming the light emitting layer. Then, the method proceeds to a step S16.

The step S16 of FIG. 16 is a step of performing a surface treatment on the element substrate 601 on which the positive hole injection/transportation layers 617a have been formed. In the step S16, the surface treatment is performed as follows. If the positive hole injection/transportation layers 617a are made of the positive hole injection/transportation layer forming material described above, their surfaces have a lyophobic property to the three kinds of liquid bodies 84R, 84G, and 84G to be used in the following step, i.e., a step S17. Therefore, the surface treatment is performed so that at least regions in the discharged regions Q have a lyophilic property. Specifically, a solvent used for the three kinds of the liquid bodies 84R, 84G and 84B is applied and dried. The solvent is applied by spraying, spin coating, or the like. Then, the method proceeds to a step S17.

The step S17 of FIG. 16 is a step of drawing an RGB light emitting layer. In the step S17, as shown in FIG. 17D, by using the method for discharging a liquid body, the three kinds of the liquid bodies 84R, 84G and 84B containing the light emitting layer forming materials are applied to the discharged regions Q from the droplet discharge heads 50, which are allocated for the respective liquid bodies, of the liquid body discharge device 10. The liquid body 84R contains a material for forming the light emitting layer 617R (red), the liquid body 84G contains a material for forming the light emitting layer 617G (green), and the liquid body 84B contains a material for forming the light emitting layer 617B (blue). The landed liquid bodies 84R, 84G, and 84B wet and spread on the surfaces of the discharged regions Q, and disposed in the discharged regions Q with a raised surface having a sectional shape of an arc. Then, the method proceeds to a step S18.

The step S18 in FIG. 16 is a step of drying and film-forming. In the step S18, as shown in FIG. 17E, solvent components of the liquid bodies 84R, 84G, and 84B discharged and drawn are dried and removed so that the light emitting layers 617R, 617G and 617B are layered on the positive hole injection/transportation layers 617a of the discharged regions Q. The element substrate 601 on which the liquid bodies 84R, 84G and 84B are discharged and drawn is preferable dried by reduced pressure drying, which allows the evaporation speed of the solvent to be approximately constant. Then, the method proceeds to a step S19.

The step S19 of FIG. 16 is a step of forming a negative electrode. In the step S19, as shown in FIG. 17F, the negative electrode 604 is formed so as to cover the light emitting layers 617R, 617G and 617B of the element substrate 601 and the surfaces of the upper layer banks 618b. The negative electrode 604 is preferably made of a combination of metals such as Ca, Ba and Al and a fluoride such as LiF. Particularly, a film made of Ca, Ba or LiF having a small work function is preferably formed on a side near the light emitting layer whereas a film made of Al and the like having a large work function is formed on a side distant from the light emitting layer. In addition, a protective layer made of SiO₂, SiN and the like may be layered on the negative electrode 604. This can prevent the negative electrode 604 from being oxidized. The negative electrode 604 may be formed by vacuum deposition, sputtering, chemical vapor deposition (CVD), or the like. Among them, the vacuum deposition is preferable since the negative electrode formed by the vacuum deposition can prevent the negative electrode from being damaged by heat of the light emitting layer. The element substrate 601 is used for manufacturing the organic EL device 600.

According to the method for manufacturing the organic EL device 600, the three kinds of liquid bodies 84R, 84G, and 84B are discharged by using the method for discharging a liquid body to the two kinds of discharged regions Q of the element substrate 601 in the step of drawing the light emitting layer to form the light emitting layers 617R, 617G, and 617B of three color elements. The two kinds of discharged regions Q are perpendicular and have different required specifications and features such as areas and arrangement directions. The method can reduce unevenness in the thicknesses of the light emitting layers 617R, 617G, and 617B formed in the two kinds of discharged regions Q, and can manufacture at least two kinds of organic EL devices 600, which have different arrangement directions of light emitting element sections 603 serving as organic EL elements, with high productivity.

The method can narrow the droplet landed intervals in the Y direction in the film forming regions 103r′, 103g′, and 103b′ in which the number of nozzles 52 allocated to discharge liquid bodies thereto is limited since the regions have a small area. As a result, the supply amounts of the droplets D1 and D2 can be increased. That is, liquid bodies can be stably supplied with predetermined amounts. This stable supply can reduce that liquid bodies are eccentrically landed positions in the film forming regions 103r′, 103g′, and 103b′, enabling at least two kinds of thin films to be manufactured with stable quality. Consequently, the method can contribute to improve the productivity of color filters.

The embodiments of the invention can be modified in various manners within the scope of the invention. The followings are exemplified modifications other than the embodiments described above.

First Modification

The layout of the first panels E1 and the second panels E2 on the mother substrate B in the embodiments is not limited but is an example. The first panels E1 and the second panels E2 may be arranged in any layout as long as the layout has a certain regularity. The first discharged regions and the second discharged regions of the embodiments are arranged in a stripe layout, but the layout is not limited to this. They may be arranged in a mosaic layout or in a delta layout.

Second Modification

In the above embodiment, the first discharged regions and the second discharged regions have different areas, but they are not limited. The method for discharging a liquid body can also be applied to a case in which the first and the second discharged regions have the same areas but different arrangement directions.

The methods for discharging a liquid body are described one by one in each example described above. The method can be singly employed or the methods can be employed as a combination thereof.

What is claimed is:

1. A method for discharging a liquid body, comprising:
discharging the liquid body to a plurality of discharged regions provided to a substrate from a plurality of nozzles each of which discharges the liquid body as a droplet and that are disposed in a linear manner as a nozzle line while the nozzle line and the substrate are relatively moved in a main scan direction approximately perpendicular to an arrangement direction of the nozzle line,
wherein each of the plurality of the discharged regions is composed of a first discharged region and a second discharged region; an area of the first discharged region is different from an area of the second discharged region; and in the discharging the liquid body, a discharge condition of the liquid body to the first discharged region is set to be different from a discharge condition of the liquid body to the second discharged region.

2. The method for discharging a liquid body according to claim 1, wherein a droplet applying density of the droplet discharged from the nozzles in the first discharged region is set to be different from a droplet applying density of the droplet discharged from the nozzles in the second discharged region.

3. The method for discharging a liquid body according to claim 1, wherein a relative speed of the substrate and the nozzle line in the main scan direction in discharging the liquid body to the first discharged region is set to be different from a relative speed of the substrate and the nozzle line in the main scan direction in discharging the liquid body to the second discharged region.

4. The method for discharging a liquid body according to claim 1, wherein a discharge period in which the liquid body is discharged from the nozzles to the first discharged region is set to be different from a discharge period in which the liquid body is discharged from the nozzles to the second discharged region.

5. The method for discharging a liquid body according to claim 1, wherein, in the discharging the liquid body, a discharge amount of the liquid body discharged from the nozzles to the first discharged region is set to be different from a discharge amount of the liquid body discharged from the nozzles to the second discharged region.

6. The method for discharging a liquid body according to claim 1, wherein the discharging the liquid body further includes relatively moving the nozzle line and the substrate in a sub scan direction perpendicular to the main scan direction while the nozzle line and the substrate are relatively moved a plurality of times in the main scan direction, and
wherein at least one of the number of relative movements in the main scan direction and a moving amount in the sub scan direction in discharging the liquid body to the first discharged region is set to be different from at least one of the number of relative movements in the main scan direction and the moving amount in the sub scan direction in discharging the liquid body to the second discharged region.

7. The method for discharging a liquid body according to claim 1, wherein the first and the second discharged regions are formed in an approximately rectangular shape, and a long side direction of the first discharged region on the substrate is disposed approximately in parallel with a long side direction of the second discharged region.

8. The method for discharging a liquid body according to claim 1, wherein the first and the second discharged regions are formed in an approximately rectangular shape, and a long side direction of the first discharged region on the substrate is disposed approximately perpendicular to a long side direction of the second discharged region.

9. A method for manufacturing a color filter, comprising:
discharging a plurality of colored liquid bodies containing colored layer forming materials to a plurality of discharged regions including first discharged regions and second discharged regions on a substrate by using the method for discharging a liquid body according to claim 1; and
solidifying the discharged liquid bodies so as to form a plurality of colored layers.

10. A method for manufacturing an organic electroluminescence (EL) device that includes a plurality of organic EL elements having functional layers having light emitting layers, comprising:
discharging a liquid body containing a light emitting layer forming material to a plurality of discharged regions including first discharged regions and second discharged regions on a substrate by using the method for discharging a liquid body according to claim 1; and
solidifying the discharged liquid body so as to form the light emitting layers.
